(19) United States
(12) Patent Application Publication
(10) Pub. No.: US 2026/0171149 A1
(43) Pub. Date: Jun. 18, 2026

(54) RESISTIVE RANDOM ACCESS MEMORY CELL ARRAY

(71) Applicant: Silicon Storage Technology, Inc., San Jose, CA (US)

(72) Inventors: Hieu Van Tran, San Jose, CA (US); Hoa Vu, San Jose, CA (US); Thuan Vu, San Jose, CA (US); Kha Nguyen, Ho Chi Minh (VN); Anh Ly, San Jose, CA (US); Feng Zhou, San Jose, CA (US); Hien Pham, Ho Chi Minh (VN)

(21) Appl. No.: 19/536,201

(22) Filed: Feb. 10, 2026

Related U.S. Application Data
(62) Division of application No. 18/782,010, filed on Jul. 23, 2024.
(60) Provisional application No. 63/642,637, filed on May 3, 2024.

(51) Int. Cl. G11C 13/00; H10B 63/00; H10N 70/00

(52) U.S. Cl. CPC G11C 13/004; G11C 13/0026; G11C 13/003; G11C 13/0061; H10B 63/30; H10N 70/821; G11C 2213/79

(57) ABSTRACT

Numerous examples are disclosed of systems and methods for operating one or more arrays of resistive random access memory (RRAM) cells. In one example, a system comprises an array of resistive random access memory (RRAM) units arranged in rows and columns; and a sense amplifier for determining a differential value stored in a first RRAM unit and a second RRAM unit in the array, wherein the first RRAM unit comprises a first select transistor coupled to a first set of one or more RRAM cells and the second RRAM unit comprises a second select transistor coupled to a second set of one or more RRAM cells.

### PRIORITY CLAIM

This application is a divisional of U.S. patent application Ser. No. 18/782,010, filed on Jul. 23, 2024, and titled, “Resistive Random Access Memory Cell Array,” which claims priority to U.S. Provisional Patent Application No. 63/642,637, filed on May 3, 2024, and titled, “Resistive Random Access Memory Cell Array,” both of which are incorporated by reference herein.

### TECHNICAL FIELD

Numerous examples are disclosed of systems and methods for operating one or more arrays of resistive random access memory cells.

### BACKGROUND OF THE INVENTION

Resistive random access memory (RRAM) is a type of nonvolatile memory. Generally, RRAM memory cells each include a resistive dielectric material layer sandwiched between two conductive electrodes. The dielectric material is normally insulating. However, by applying the proper voltage across the dielectric layer, a conduction path (typically referred to as a filament) can be formed through the dielectric material layer. Once the filament is formed, it can be “reset” (i.e., broken or ruptured, resulting in a high resistance state across the RRAM cell) and set (i.e., re-formed, resulting in a lower resistance state across the RRAM cell), by applying the appropriate voltages and currents across the dielectric layer. The low and high resistance states (i.e., LRS and HRS) can be utilized to indicate a digital signal of “1” or “0” depending upon the resistance state, and thereby provide a reprogrammable non-volatile memory cell that can store a bit of information.

FIG. 1 shows a conventional configuration of an RRAM memory cell 1. Memory cell 1 includes a resistive dielectric material layer 2 sandwiched between two conductive material layers that form top and bottom electrodes 3 and 4, respectively. More than one dielectric material layers are possible.

FIGS. 2A-2D show the switching mechanism of the dielectric material layer 2. Specifically, FIG. 2A shows the resistive dielectric material layer 2 in its initial state after fabrication, where the layer 2 exhibits a relatively high resistance. FIG. 2B shows the formation of a conductive filament 7 through the layer 2 by applying the appropriate voltage across the layer 2. The filament 7 is a conductive path through the layer 2, such that the layer exhibits a relatively low resistance across it (because of the relatively high conductivity of the filament 7). FIG. 2C shows the formation of a rupture 8 in filament 7 caused by the application of a “reset” voltage across the layer 2. The area of the rupture 8 has a relatively high resistance, so that layer 2 exhibits a relatively high resistance across it. FIG. 2D shows the restoration of the filament 7 in the area of the rupture 8 caused by the application of a “set” voltage across layer 2. The restored filament 7 means the layer 2 exhibits a relatively low resistance across it. The relatively low resistance of layer 2 in the “formation” or “set” states of FIGS. 2B and 2D respectively can represent a digital signal state (e.g. a “1”), and the relatively high resistance of layer 2 in the “reset” state of FIG. 2C can represent a different digital signal state (e.g. a “0”). The RRAM cell 1 can repeatedly be “reset” and “set,” so it forms an ideal reprogrammable nonvolatile memory cell.

Applicant designed another example of an RRAM memory cell that was described in U.S. patent application Ser. No. 14/582,089, published as United States Patent Application Publication 2516/0181517, which is incorporated herein by reference. That application presented an improved RRAM memory cell that used a lower voltage and current for forming the cell's filament. Specifically, that application disclosed a geometrically enhanced RRAM cell with electrodes and resistive dielectric layer configured in a manner that reduces the voltage necessary for forming the cell's conductive filament. Applicant had discovered that by providing a sharp corner in the resistive dielectric layer at a point between the two electrodes significantly reduces the voltage and current necessary to effectively form the filament. This design will be described below with reference to FIGS. 3-6.

FIG. 3 illustrates the general structure of RRAM memory cell 10, which includes a resistive dielectric layer 12 having elongated first and second portions 12a and 12b respectively that meet at a right angle. Specifically, first portion 12a is elongated and extends horizontally, and second portion 12b is elongated and extends vertically, such that the two portions 12a and 12b meet at a sharp corner 12c (i.e. resistive dielectric layer 12 has an “L” shape). The first electrode 14 is disposed above horizontal layer portion 12a and to the left of vertical layer portion 12b. The second electrode 16 is disposed below horizontal layer portion 12a and to the right of vertical layer portion 12b. Therefore, each of the first and second layer portions 12a and 12b are disposed between and in electrical contact with the electrodes 14 and 16. Electrodes 14 and 16 can be formed of appropriately conductive material such as W, Al, Cu, Ti, Pt, TaN, TiN, or other materials, and resistive dielectric layer 12 is made of a transition metal oxide, such as HfOx, TaOx, TiOx, WOx, VOx, CuOx, or multiple layers of such materials). Alternatively, resistive dielectric layer 12 can be a composite of discrete sub-layers with one or more sub-layers of transition metal oxides (e.g. layer 12 could be multiple layers: an Hf layer disposed between a TaOx layer and an HfOx layer). It has been discovered that filament formation through layer 12 at the sharp corner 12c can occur at lower voltages than if the dielectric layer 12 were planar due to the enhanced electric field at the sharp corner 12c.

FIGS. 4A-4C show actions to form the inventive RRAM memory cell 10 and related circuitry. The process begins by forming a select transistor on a substrate 18. The transistor includes source/drain regions 20/22 formed in the substrate 18 and a gate 24 disposed over and insulated from the channel region there between. On the drain 22 is formed conductive blocks 26 and 28, and conductive plug 30, as illustrated in FIG. 4A.

A layer of conductive material 32 is formed over plug 30 (e.g. using prior art photolithography techniques). A block of conductive material 34 is then formed over just a portion of the layer of conductive material 32. The corner where layer 32 and block 34 meet can be sharpened by plasma treatment. Then, transition metal oxide layer 36 is deposited on layer 32 and on the vertical portion of block 34. This is followed by a conductive material deposition and CMP etch back to form a block of conductive material 38 on layer 36. The resulting structure is shown in FIG. 4B.

A conductive plug 40 is formed on conductive block 38. A conductive line (e.g. bit line) 42 is formed over and connected to plug 40. The resulting structure is shown in FIG. 4C. Layer 32 and block 34 form the lower electrode 16, layer 36 forms the resistive dielectric layer 12, and block 38 forms the upper electrode 14, of RRAM cell 10. FIG. 4C further contains a schematic representation for an RRAM memory cell, where the RRAM cell corresponds to RRAM cell 10 with its select transistor, and where BL is electrode 42, WL is electrode 24, and SL is electrode 20.

Optionally, the location of RRAM cell 10 and the select transistor can be swapped, such that one terminal of the select transistor is coupled to BL, the gate 24 of the select transistor received WL, and the other terminal of the select transistor is coupled to RRAM cell 10 and where one terminal of RRAM cell 10 is coupled to the select transistor and the other terminal is coupled to SL.

FIGS. 5A-5C show actions to form an alternate example of the inventive RRAM memory cell 10 and related circuitry. The process begins by forming the select transistor on a substrate 18 as described above (source/drain regions 20/22 formed in the substrate 18, and gate 24 disposed over and insulated from the channel region there between). On the drain 22 is formed a conductive block 44, as illustrated in FIG. 5A.

A layer of conductive material 46 is formed over block 44. A transition metal oxide layer 48 is deposited on block 46, along one of the vertical side surfaces of block 46, and away from block 46. This is followed by forming a layer of conductive material 50 by deposition and CMP etch back. The resulting structure is shown in FIG. 5B. Hence, there exists a sharp tip corner 46a of material 46 that is pointing to another sharp tip corner intersection of layers 48/50. This enhances the localized field at top corner 46a which reduces the necessary forming voltage.

A conductive plug 52 is formed on conductive layer 50. A conductive line (e.g. bit line) 54 is formed over and connected to plug 52. The resulting structure is shown in FIG. 5C. Layer 46 forms the lower electrode 16, layer 48 forms the resistive dielectric layer 12, and layer 50 forms the upper electrode 14, of RRAM cell 10.

As a non-limiting example, RRAM cell 10 in its original state is shown in FIG. 6A. Electrodes 14 and 16 are formed of CU and resistive dielectric layer 12 is formed of HfOx. In order to form a conductive filament 56 through the sharp corner 12c as shown in FIG. 6B, a voltage difference of about 3-6V is applied across electrodes 14 and 16. In order to reset the RRAM cell 10 by forming a rupture 58 in filament 56 as shown in FIG. 6C, a voltage difference of about 1-4 V is applied across electrodes 14 and 16. In order to set the RRAM cell 10 by removing rupture 58 in filament 56 as shown in FIG. 6D, a voltage difference of about 1-4 Vis applied across electrodes 16 and 14 (i.e. reverse polarity relative to forming and reset voltages).

Optionally, the location of RRAM cell 10 and the select transistor can be swapped, such that one terminal of the select transistor is coupled to BL, the gate 24 of the select transistor received WL, and the other terminal of the select transistor is coupled to RRAM cell 10 and where one terminal of RRAM cell 10 is coupled to the select transistor and the other terminal is coupled to SL.

Table 1 depicts an example set of voltages that can be applied to RRAM cell 10 of FIGS. 4-6 to perform form, set, and reset operations and the resulting current, Icell, through RRAM cell 10:

TABLE 1
OPERATING VOLTAGES

| | WL | BL | | SL | | Icell | |
|---|---|---|---|---|---|---|---|
| Read | 1-2 V | 0.1-2 | V | 0 | V | 10-30 | μA |
| Reset | 1-2 V | 0 | V | 1-2 | V | 100-200 | μA |
| Set | 1-2 V | 1-2 | V | 0 | V | 100-200 | μA |
| Form | 1-2 V | 1-2 | V | 0 | V | 100-200 | μA |

Applicants designed another example of an RRAM memory cell that was described in U.S. patent application Ser. No. 17/199,243, issued as U.S. Pat. No. 11,646,078, which is incorporated herein by reference. That design will be described with reference to FIGS. 7A and 7B.

FIG. 7A depicts an example of RRAM cell 700. RRAM cell 700 comprises top electrode 710, bottom electrode 740, reservoir layer 720, and switching layer 730. In one example, top electrode 710 and bottom electrode 740 are constructed with TiN, reservoir layer 720 is constructed with Ti, and switching layer 730 is constructed with HfOx. In the alternative, top electrode 710 and bottom electrode 740 can be constructed with Pt, W, Ta, Al, Ru, or Ir. Switching layer 730 can be constructed with TaOx, AlOx, or Wox, or other materials. Switching layer 730 also be constructed from any single layer oxide, or with an oxygen scavenger metal such as Ti, or it could be constructed with multiple layers combing different oxides and metals such as HfO2/Al2O3, HfO2/Hf/TaOx, or HfO2/Ti/TiOx.

As shown in FIG. 7B, RRAM cell 700 is connected to selector 750 (for cell selection purpose), creating an RRAM memory cell (bit-cell). In this drawing, selector 750 is a transistor with its drain connecting to the bottom electrode 740 of RRAM cell 700, its gate connecting to a wordline of an array in which RRAM cell 700 is located, and its source connecting to a sourceline of the array. Top electrode 710 of RRAM cell 700 connects to a bitline of an array. Alternative examples for the selector can include a bi-directional diode or a switch.

Optionally, the location of RRAM cell 700 and the select transistor 750 can be swapped, such that one terminal of select transistor 750 is coupled to BL, the gate of select transistor 750 receives WL, and the other terminal of select transistor 750 is coupled to RRAM cell 700 and where one terminal of RRAM cell 700 is coupled to select transistor 750 and the other terminal is coupled to SL.

As discussed earlier, the set operation in a RRAM cell can be performed to write a “1” to the cell, and a reset operation can be performed to write a “0” to the cell.

With reference to Table 2, the following example voltages and currents can be applied to memory cell 700 to perform form, set, and reset operations:

TABLE 2
OPERATING VOLTAGES

| | Top Electrode 710 | Bottom Electrode 740 |
|---|---|---|
| Form | Vform | Iformcomp |
| Set | Vset | Isetcomp |
| Reset | Iresetcomp | Vreset |

Vform ~ 1-4 V
Iformcomp ~ 100 pA-20 uA
Vset ~ 0.3-1 V
Isetcomp ~10-50 uA
Vreset ~0.5-1.5 V
Iresetcomp ~ 20-150 uA

When an array of RRAM is created, bit lines, word lines, and source lines can be utilized to select cells for a form, set, or reset operation or to unselect cells for a form, set, or reset operation. Wordlines, sourcelines and bitlines are used for selecting RRAM memory cells for form/set/reset/read operation. A selected wordline is used to couple the bottom electrode of a RRAM cell to ground in form/read/set and to a reset voltage in reset. A selected bitline is used to provide a form/set bias in form/set/read operation and to provide a ground level in reset. A selected sourceline is used to provide ground level in form/set/read operation and a reset bias in reset operation. For unselected terminals (SL/BL/WL), appropriate inhibit biases are used to prevent disturb (unwanted cell behavior). Examples of the voltages and currents that can be applied to these lines are shown in Tables 3 and 4:

TABLE 3
OPERATING VOLTAGES
Array Operation 1

| | BL | | WL | | SL | |
|---|---|---|---|---|---|---|
| | selected | unselected | selected | unselected | selected | unselected |
| | cell | cell | cell | cell | cell | cell |
| READ 1 | Vblrd | 0 v | Vwlrd | 0 v | 0 v | 0 v |
| READ 2 | 0 v | 0 v | Vwlrd | 0 v | Vslrd | 0 v |
| FORM -V | Vblform, I | float/Vblformbias- | Vwlform | Vwlformbias- | 0 v | float/Vslformbias- |
| | compliance | unsel | | unsel | | unsel |
| FORM -I | Iblform, | float/Vblformbias- | Vwlform | Vwlformbias- | 0 v | float/Vslformbias- |
| | V compliance | unsel | | unsel | | unsel |
| SET | Vblset, Iblset | 0 v | Vwlset | 0 v | 0 v | 0 v |
| RESET | 0 v/Vblreset, | Vblresetbias- | Vwlreset | 0 v | Vslreset, | 0 v |
| | Iblreset | unsel/float | | | Islreset | |

TABLE 4
OPERATING VOLTAGES
Array Operation 2

| | SL | | WL | | BL | |
|---|---|---|---|---|---|---|
| | selected | unselected | selected | unselected | selected | unselected |
| | cell | cell | cell | cell | cell | cell |
| READ 1 | Vslrd | 0 v | Vwlrd | 0 v | 0 v | 0 v |
| READ 2 | 0 v | 0 v | Vwlrd | 0 v | Vblrd | 0 v |
| FORM -V | Vslform, I | float/Vslformbias- | Vwlform | Vwlformbias- | 0 v | float/Vblformbias- |
| | compliance | unsel | | unsel | | unsel |
| FORM -I | Islform, V | float/Vslformbias- | Vwlform | Vwlformbias- | 0 v | float/Vblformbias- |
| | compliance | unsel | | unsel | | unsel |
| SET | Vslset, Islset | 0 v | Vwlset | 0 v | 0 v | 0 v |
| RESET | 0 v/Vslreset, | Vslresetbias- | Vwlreset | 0 v | Vblreset. | 0 v |
| | Islreset | unsel/float | | | Iblreset | |

In Array Operation 1 and Array Operation 2 of Tables 2 and 3, READ 2 is a reversed read of READ1, meaning the BL and SL terminals are interchanged during a read operation. In Array Operation 1, a high voltage is applied to the bitline for form and set operation and to the sourceline for reset operation. In Array Operation 2, a high voltage is applied to the source line for form and set operations and to the bit line for a reset operation. In Tables 1 and 2, “FORM-V” means forming with a voltage bias (fixed, ramp, or increment/decrement step) with a current compliance. “FORM-I” means forming with a current bias (fixed, ramp, or increment/decrement step) with a voltage compliance. In FORM-V or FORM-I, unselected wordlines are biased at a bias level to increase the breakdown of the un-selected select transistors.

FIG. 8 depicts RRAM array 800, which comprises an array of RRAM units arranged in rows and columns, where each column is coupled to a bit line (BL) and source line (SL) and each row is coupled to a word line (WL). RRAM units 801 and 811 are examples of a vertically-adjacent pair of RRAM units and it is understood that the other RRAM units in RRAM array 800 have the same structure as RRAM unit 801 or RRAM unit 811. In RRAM array 800, each RRAM unit comprises a single select transistor and a single RRAM cell.

RRAM unit 801 comprises select transistor 802 and RRAM cell 803. A first terminal of select transistor 802 is coupled to bit line BL0, a second terminal of select transistor 802 is coupled to a first terminal of RRAM cell 803, and a gate of select transistor 802 is coupled to word line WL0. A second terminal of RRAM cell 803 is coupled to source line SL0.

RRAM unit 811 comprises select transistor 812 and RRAM cell 813. A first terminal of select transistor 812 is coupled to bit line BL0, a second terminal of select transistor 812 is coupled to a first terminal of RRAM cell 813, and a gate of select transistor 812 is coupled to word line WL1. A second terminal of RRAM cell 813 is coupled to source line SL0.

FIG. 9 depicts RRAM array 900, which is similar to RRAM array 800 in FIG. 8 except that the roles of the bit lines and source lines are swapped. RRAM array 900 comprises an array of RRAM units arranged in rows and columns, where each column is coupled to a bit line (BL) and source line (SL) and each row is coupled to a word line (WL). RRAM units 901 and 911 are examples of a vertically-adjacent pair of RRAM units and it is understood that the other RRAM units in RRAM array 900 have the same structure as RRAM unit 901 or RRAM unit 911. In RRAM array 900, each RRAM unit comprises a single select transistor and a single RRAM cell.

RRAM unit 901 comprises select transistor 902 and RRAM cell 903. A first terminal of select transistor 902 is coupled to source line SL0, a second terminal of select transistor 902 is coupled to a first terminal of RRAM cell 903, and a gate of select transistor 902 is coupled to word line WL0. A second terminal of RRAM cell 903 is coupled to bit line BL0.

RRAM unit 911 comprises select transistor 912 and RRAM cell 913. A first terminal of select transistor 912 is coupled to source line SL0, a second terminal of select transistor 912 is coupled to a first terminal of RRAM cell 913, and a gate of select transistor 912 is coupled to word line WL1. A second terminal of RRAM cell 913 is coupled to bit line BL0.

FIG. 10 depicts RRAM array 1000, which comprises an array of RRAM units arranged in rows and columns, where each column is coupled to a bit line (BL) and two source lines (SLA and SLB) and each row is coupled to a word line (WL). RRAM units 1001 and 1011 are examples of a vertically-adjacent pair of RRAM units and it is understood that the other RRAM units in RRAM array 1000 have the same structure as RRAM unit 1001 or RRAM unit 1011. In RRAM array 1000, each RRAM unit comprises a single select transistor and two RRAM cells (i.e., 1TnR, n=2).

RRAM unit 1001 comprises select transistor 1002 and RRAM cells 1003 and 1004. A first terminal of select transistor 1002 is coupled to bit line BL0, a second terminal of select transistor 1002 is coupled to a first terminal of RRAM cell 1003 and a first terminal of RRAM cell 1004, and a gate of select transistor 1002 is coupled to word line WL0. A second terminal of RRAM cell 1003 is coupled to source line SL0A, and a second terminal of RRAM cell is coupled to source line SLOB.

RRAM unit 1011 comprises select transistor 1012 and RRAM cells 1013 and 1014. A first terminal of select transistor 1012 is coupled to bit line BL0, a second terminal of select transistor 1012 is coupled to a first terminal of RRAM cell 1013 and a first terminal of RRAM cell 1014, and a gate of select transistor 1012 is coupled to word line WL1. A second terminal of RRAM cell 1013 is coupled to source line SL0A, and a second terminal of RRAM cell 1014 is coupled to source line SLOB.

FIG. 11B depicts RRAM array 1120, which is similar to RRAM array 1100 in FIG. 11 except each RRAM unit comprises two RRAM cells connect to a select transistor and the same metal lines (e.g., the same BL and the same SL). Thus, RRAM array 1120 comprises an array of RRAM units arranged in rows and columns, where each column is coupled to a bit line (BL) and a source line and each row is coupled to a word line (WL). RRAM units 1121 and 1131 are examples of a vertically-adjacent pair of RRAM units and it is understood that the other RRAM units in RRAM array 1120 have the same structure as RRAM unit 1121 or RRAM unit 1131. In RRAM array 1120, each RRAM unit comprises a single select transistor and two RRAM cells (i.e., 1TnR, n=2).

RRAM unit 1121 comprises select transistor 1122 and RRAM cells 1123 and 1124. A first terminal of select transistor 1122 is coupled to source line SL0, a second terminal of select transistor 1122 is coupled to a first terminal of RRAM cell 1703 and a first terminal of RRAM cell 1124, and a gate of select transistor 1122 is coupled to word line WL0. A second terminal of RRAM cell 1123 and a second terminal of RRAM cell 1124 are coupled to bit line BL0.

RRAM unit 1131 comprises select transistor 1132 and RRAM cells 1133 and 1134. A first terminal of select transistor 1132 is coupled to source line SL0, a second terminal of select transistor 1132 is coupled to a first terminal of RRAM cell 1133 and a first terminal of RRAM cell 1134, and a gate of select transistor 1132 is coupled to word line WL1. A second terminal of RRAM cell 1133 and a second terminal of RRAM cell 1134 are coupled to bit line BL0.

FIG. 12 depicts RRAM array 1200, which is similar to RRAM array 1000 in FIG. 10 except that the roles of the bit lines and source lines are swapped. RRAM array 1200 comprises an array of RRAM units arranged in rows and columns, where each column is coupled to two bit lines (BLA and BLB) and one source line (SL) and each row is coupled to a word line (WL). RRAM units 1201 and 1211 are examples of a vertically-adjacent pair of RRAM units and it is understood that the other RRAM units in RRAM array 1200 have the same structure as RRAM unit 1201 or RRAM unit 1211. In RRAM array 1200, each RRAM unit comprises a single select transistor and two RRAM cells.

RRAM unit 1201 comprises select transistor 1202 and RRAM cells 1203 and 1204. A first terminal of select transistor 1202 is coupled to source line SL0, a second terminal of select transistor 1202 is coupled to a first terminal of RRAM cell 1203 and a first terminal of RRAM cell 1204, and a gate of select transistor 1202 is coupled to word line WL0. A second terminal of RRAM cell 1203 is coupled to bit line BL0A, and a second terminal of RRAM cell is coupled to bit line BLOB.

RRAM unit 1211 comprises select transistor 1212 and RRAM cells 1213 and 1214. A first terminal of select transistor 1212 is coupled to source line SL0, a second terminal of select transistor 1212 is coupled to a first terminal of RRAM cell 1213 and a first terminal of RRAM cell 1214, and a gate of select transistor 1212 is coupled to word line WL1. A second terminal of RRAM cell 1213 is coupled to bit line BL0A, and a second terminal of RRAM cell 1214 is coupled to source line BLOB.

It can be appreciated that each RRAM unit in RRAM array 1200 can operate in three different modes. This will be illustrated using RRAM unit 1201 as an example, with RRAM cell 1203 storing a value IR0 (HRS) and RRAM cell 1004 storing a value IR1 (LRS). In a first mode, RRAM cell 1203 and 1204 operate as differential cells, where data is stored in differential form in the two cells (e.g., IR0-IR1 or IR1-IR0). In a second mode, RRAM cells 1203 and 1204 operate as redundant cells, where identical data is stored in each cell (e.g., IR0=IR1). In a third mode, RRAM cells 1203 and 1204 together operate as a multi-level cell to store multiple bits (e.g., IR0 is the first bit and IR1 is the second bit), which here is two bits representing four different levels that can be stored.

It is increasingly important for RRAM arrays to be operable in a reliable, fast, and precise manner. What is needed is improved circuitry and methods for operating RRAM arrays.

### SUMMARY OF THE INVENTION

Numerous examples are disclosed of systems and methods for operating one or more arrays of resistive random access memory cells.

In one example, a system comprises an array of resistive random access memory (RRAM) units arranged in rows and columns, and a sense amplifier for determining a differential value stored in a first RRAM unit and a second RRAM unit in the array.

In another example, a system comprises a first array of resistive random access memory (RRAM) units arranged in rows and columns, a second array of RRAM units arranged in rows and columns, and a sense amplifier for determining a differential value stored in a first RRAM unit in the first array and a second RRAM unit in the second array.

In another example, a system comprises an array of resistive random access memory cells arranged in rows and columns, a driver to provide current to bit lines or source lines coupled to the array, and a current limiter to limit an amount of current provided by the driver.

In another example, a method comprises placing a first read path in a differential amplifier, applying a sequence of trim settings to an offset calibration circuit coupled to a sense amplifier, and storing trim settings that result in a change in an output of the sense amplifier.

In another example, a read bias generator comprises a bias transistor, a feedback loop, a replica resistor, and a reference unit.

In another example, a system comprises an array of resistive random access memory (RRAM) units arranged in rows and columns, a sense amplifier for determining a differential value stored in a first RRAM unit and a second RRAM unit in the array, wherein the first RRAM unit comprises a first select transistor coupled to a first set of one or more RRAM cells and the second RRAM unit comprises a second select transistor coupled to a second set of one or more RRAM cells.

In another example, a system comprises an array of resistive random access memory (RRAM) units arranged in rows and columns, and a sense amplifier for determining a value stored in a RRAM unit in the array using a reference unit.

### BRIEF DESCRIPTION OF THE DRAWINGS

FIG. 1 depicts a Resistive Random Access Memory (RRAM) cell.

FIG. 2A is a side cross sectional view of the resistive dielectric layer of the RRAM cell of FIG. 1 in its initial state after fabrication.

FIG. 2B is a side cross sectional view of the resistive dielectric layer of the RRAM cell of FIG. 1 in its formed state.

FIG. 2C is a side cross sectional view of the resistive dielectric layer of the RRAM cell of FIG. 1 in its reset state.

FIG. 2D is a side cross sectional view of the resistive dielectric layer of the RRAM cell of FIG. 1 in its set state.

FIG. 3 is a side cross sectional view of another RRAM cell.

FIGS. 4A-4C are side cross sectional views showing the steps in forming the RRAM cell of FIG. 3.

FIGS. 5A-5C are side cross sectional views showing the steps in forming an alternate example of the RRAM cell of FIG. 3.

FIG. 6A is a side cross sectional view of the RRAM cell of FIG. 3 in its initial state.

FIG. 6B is a side cross sectional view of the RRAM cell of FIG. 3 in its formed state.

FIG. 6C is a side cross sectional view of the RRAM cell of FIG. 3 in its reset state.

FIG. 6D is a side cross sectional view of the RRAM cell of FIG. 3 in its set state.

FIG. 7A depicts another RRAM cell.

FIG. 7B depicts an RRAM cell with a select transistor.

FIG. 8 depicts an example of an RRAM array.

FIG. 9 depicts another example of an RRAM array.

FIG. 10 depicts another example of an RRAM array.

FIG. 11 depicts another example of an RRAM array.

FIG. 12 depicts another example of an RRAM array.

FIGS. 13A, 13B, 13C, and 13D depict RRAM units.

FIG. 14 depicts a RRAM unit.

FIG. 15 depicts a RRAM unit.

FIG. 16 depicts a RRAM unit.

FIG. 17 depicts a die comprising RRAM arrays and associated circuitry.

FIG. 18 depicts an RRAM system to store a differential value in RRAM cells in two different arrays.

FIG. 19 depicts an RRAM system to store a differential value in adjacent RRAM cells in the same array.

FIG. 20 depicts an RRAM system to store a differential value in two RRAM cells in the same array.

FIG. 21 depicts a bias application system.

FIG. 22 depicts a sense amplifier.

FIG. 23 depicts a comparator.

FIG. 24 depicts an RRAM array.

FIG. 25 depicts a bias generator.

FIG. 26 depicts a bias generator.

FIG. 27 depicts a bias generator.

FIG. 28 depicts a read reference generator.

FIG. 29 depicts a sense amplifier.

FIG. 30 depicts a sense amplifier.

FIG. 31 depicts a sense amplifier.

FIG. 32 depicts a sense amplifier.

FIG. 33 depicts a sense amplifier.

FIG. 34 depicts a sense amplifier.

FIG. 35 depicts a sense amplifier.

FIG. 36 depicts an RRAM array.

FIG. 37 depicts a sensing calibration method.

FIG. 38 depicts a set, reset, and form method.

FIG. 39 depicts an RRAM system.

FIG. 40 depicts an RRAM system.

FIG. 41 depicts an RRAM system.

FIG. 42 depicts a column driver.

FIG. 43 depicts a column driver.

FIG. 44 depicts a sense amplifier.

### DETAILED DESCRIPTION OF THE EMBODIMENTS

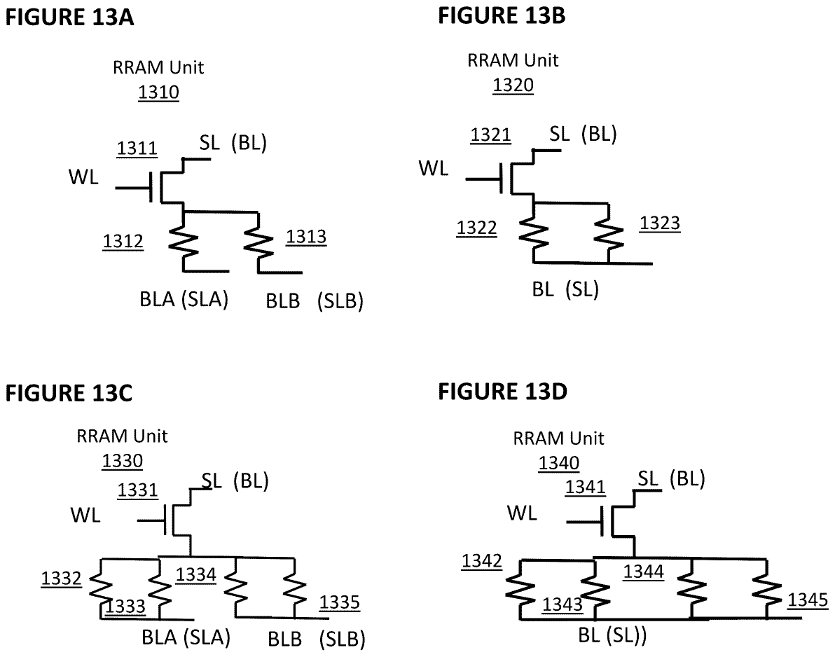

FIG. 13A depicts differential RRAM unit 1310. RRAM unit 1310 has a 1T2R format and comprises select transistor 1311 and RRAM cells 1312 and 1313, and comprises four terminals (e.g., WL, SL, BLA, and BLB, or WL, BL, SLA, and SLB).

FIG. 13B depicts RRAM unit 1320. RRAM unit 1320 has a 1T2R format and comprises select transistor 1321 and RRAM cells 1322 and 1323 connected in parallel, and comprises three terminals (e.g., WL, SL, BL).

FIG. 13C depicts differential RRAM unit 1330. RRAM unit 1330 has a 1T4R format and comprises select transistor 1331 and RRAM cells 1332, 1333, 1334, and 1335, where RRAM cells 1332 and 1333 are connected in parallel and RRAM cells 1334 and 1335 are connected in parallel, and comprises four terminals (e.g., WL, SL, BLA, and BLB, or WL, BL, SLA, and SLB).

FIG. 13D depicts RRAM unit 1340. RRAM unit 1340 has a 1T4R format and comprises select transistor 1341 and RRAM cells 1342, 1343, 1344, and 1345 connected in parallel, and comprises three terminals (e.g., WL, SL, and BL).

RRAM units 1310, 1320, 1330, and 1340 in FIGS. 13A, 13B, 13C, and 13D, respectively, can store differential values, redundant values, or multi-bit values as needed to improve performance and reliability robustness.

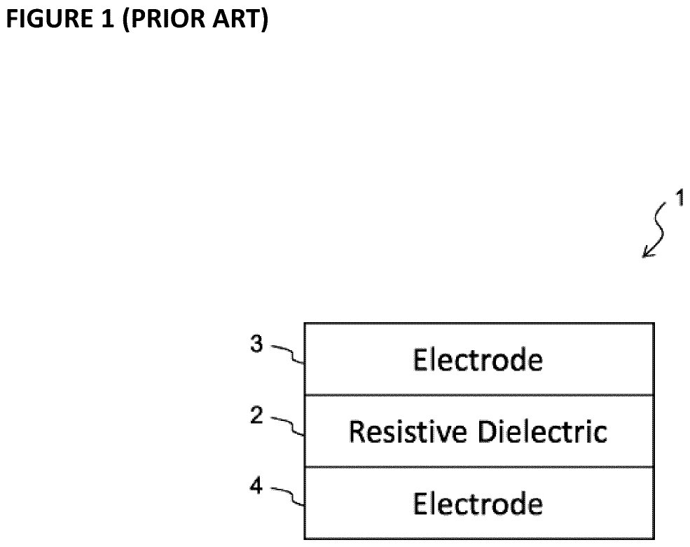

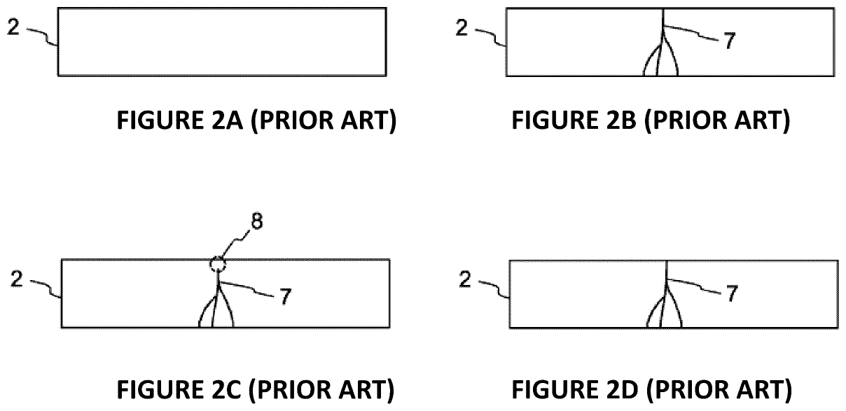

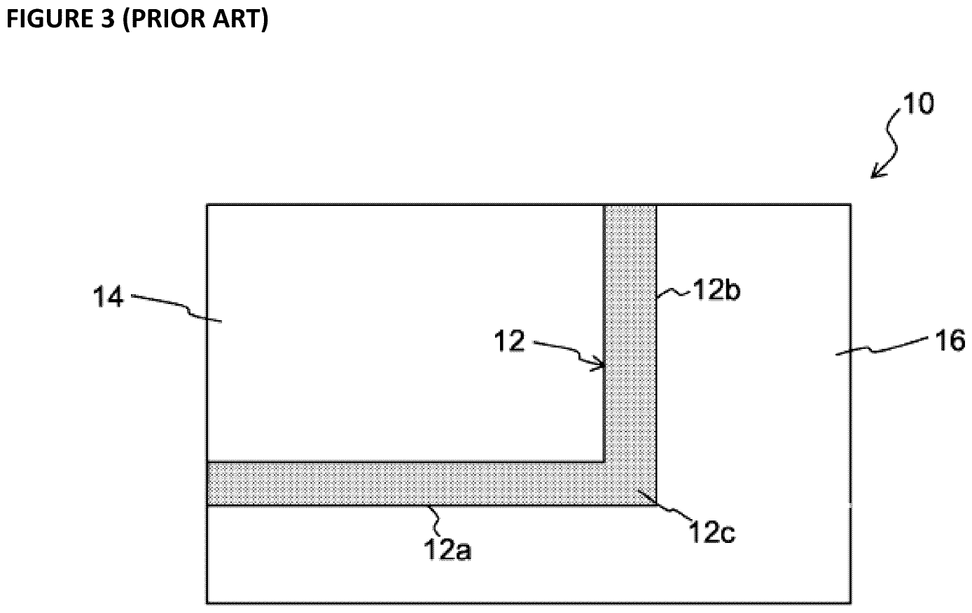

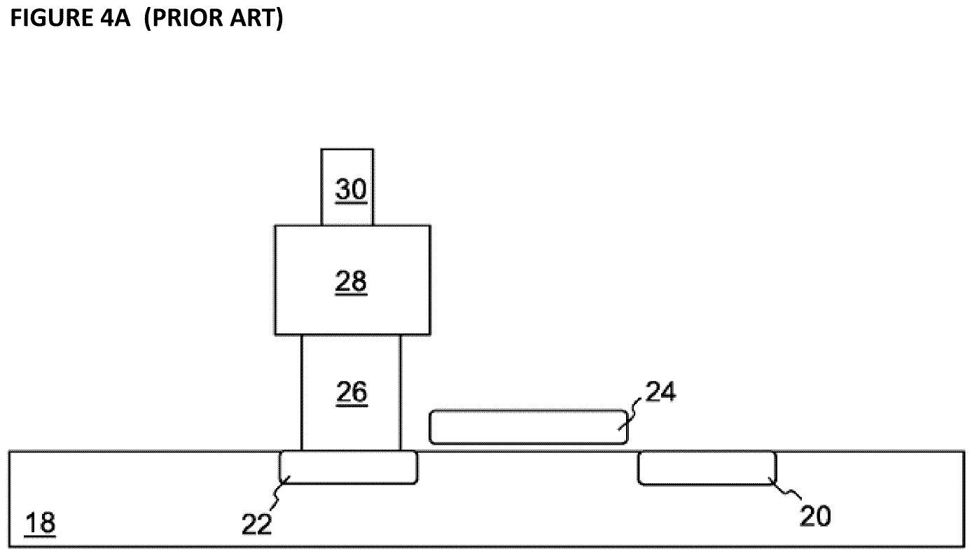

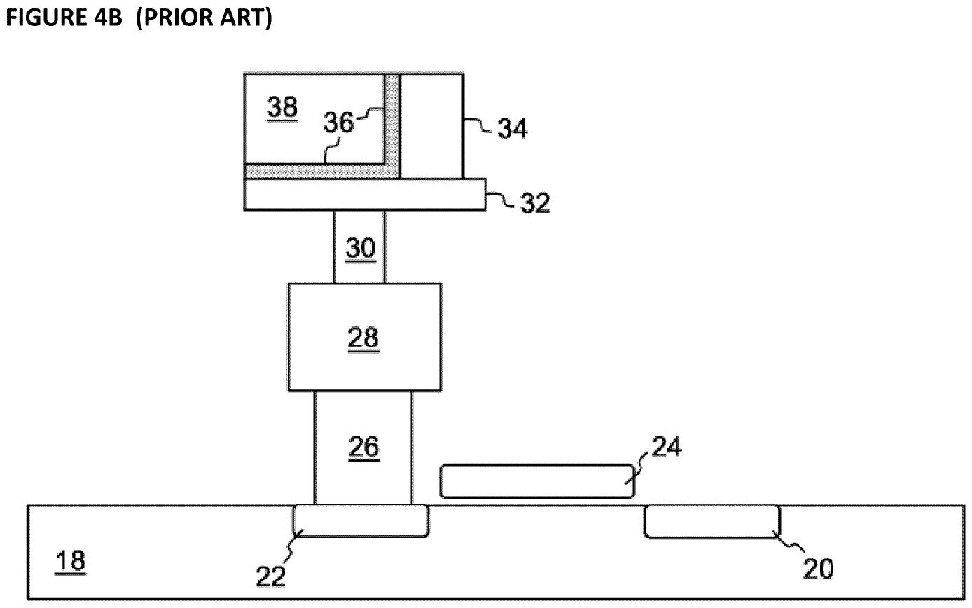

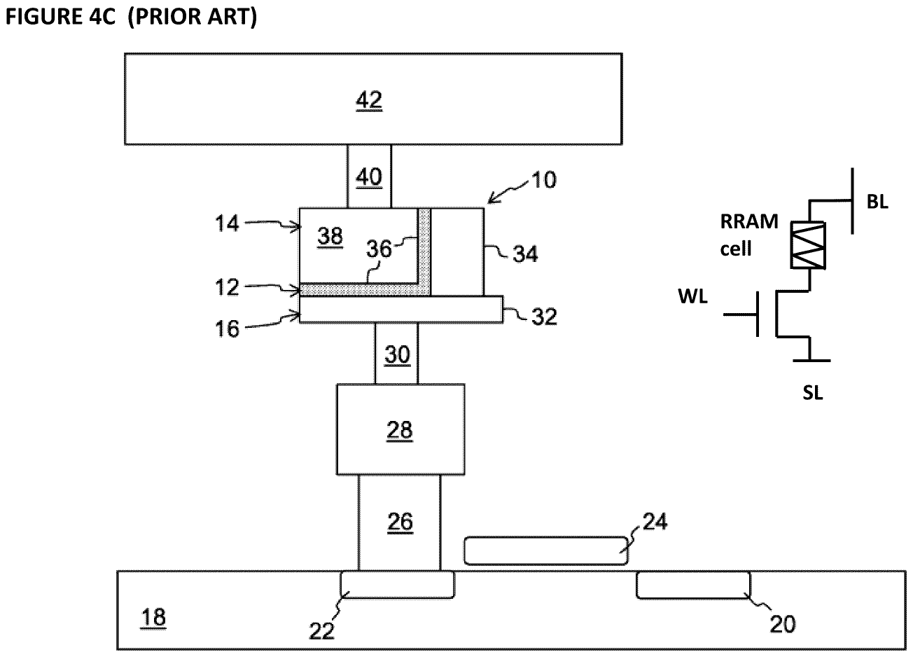

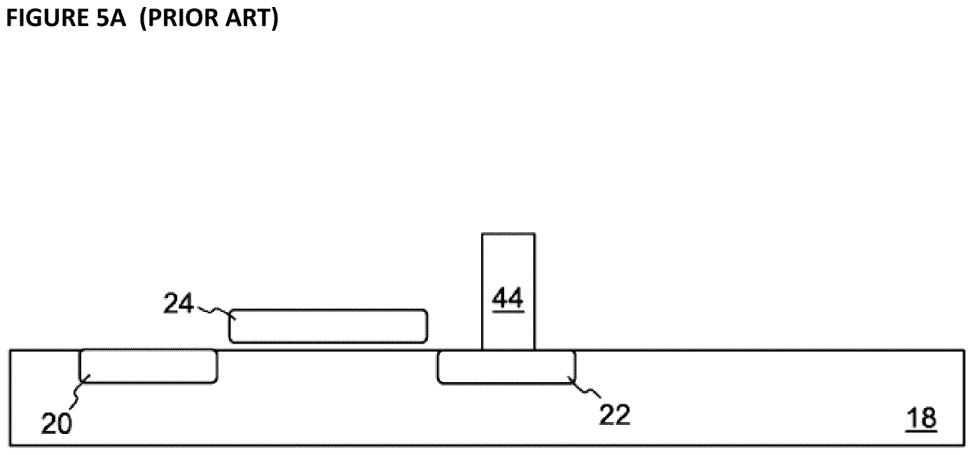

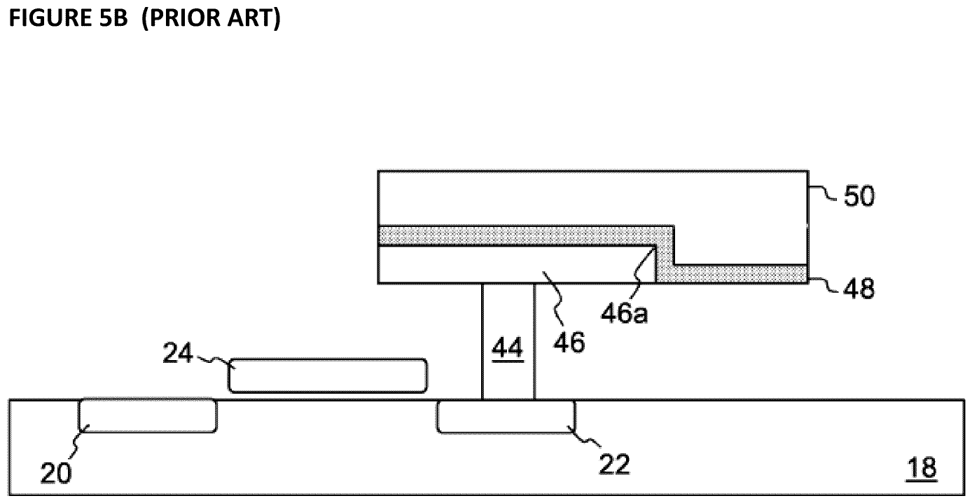

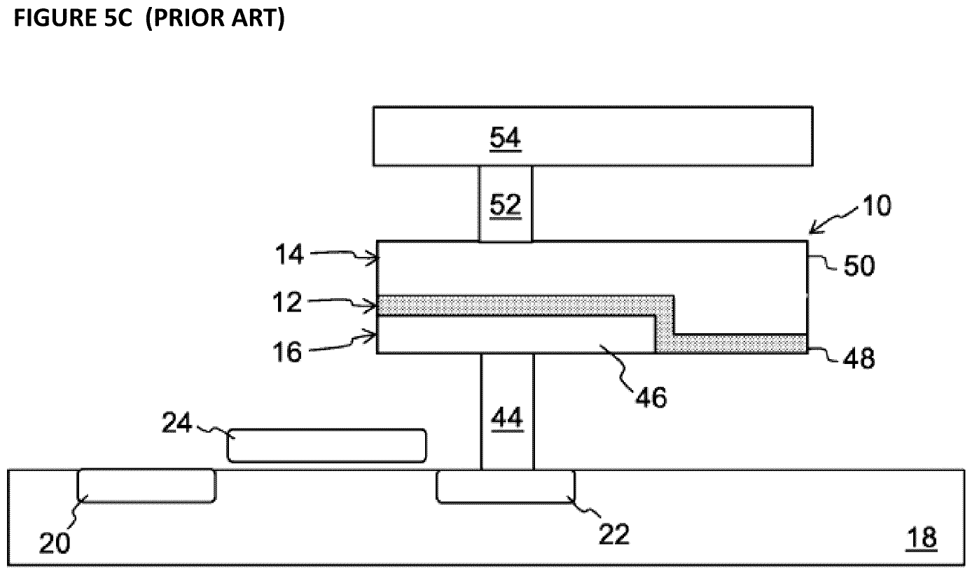

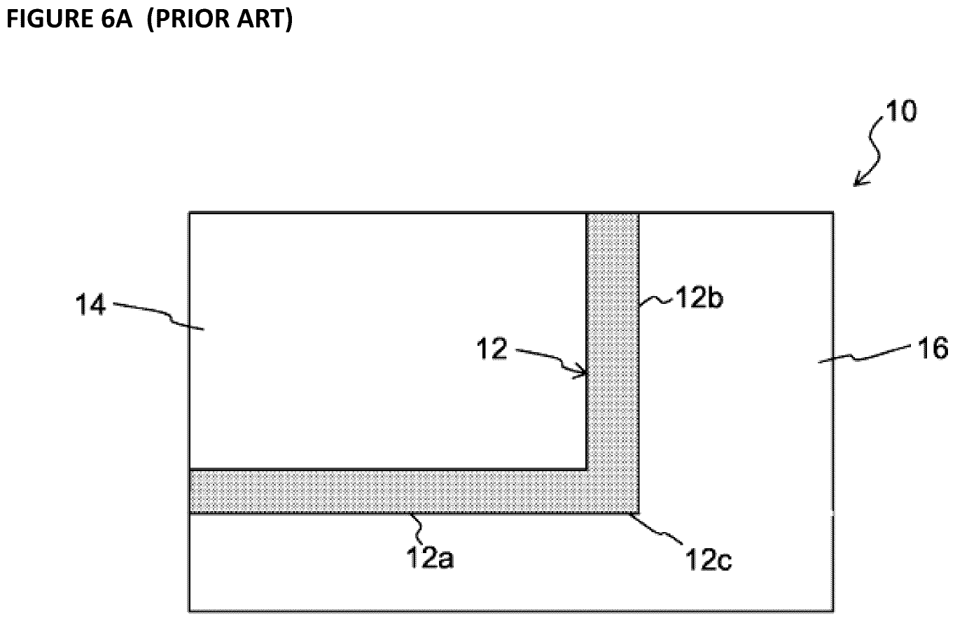

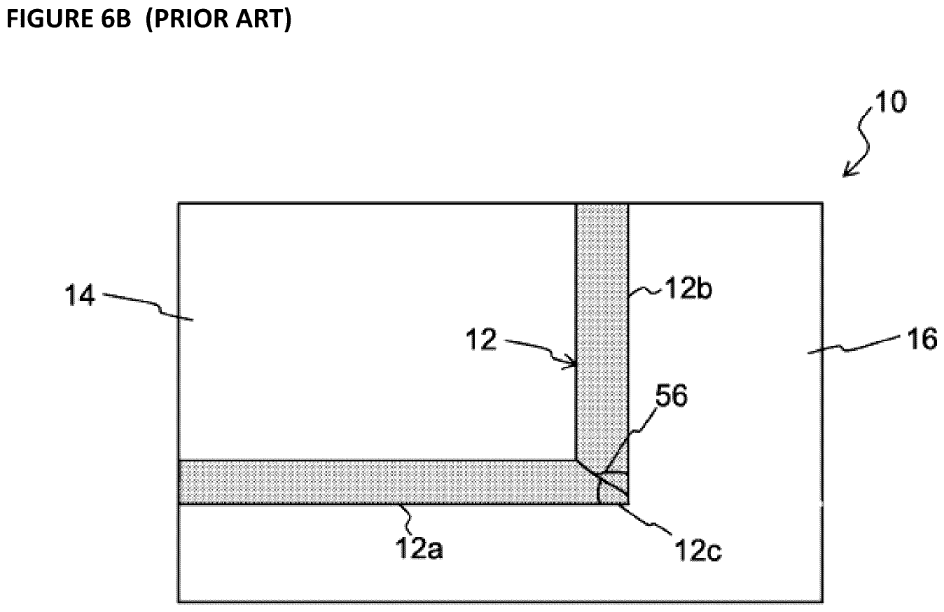

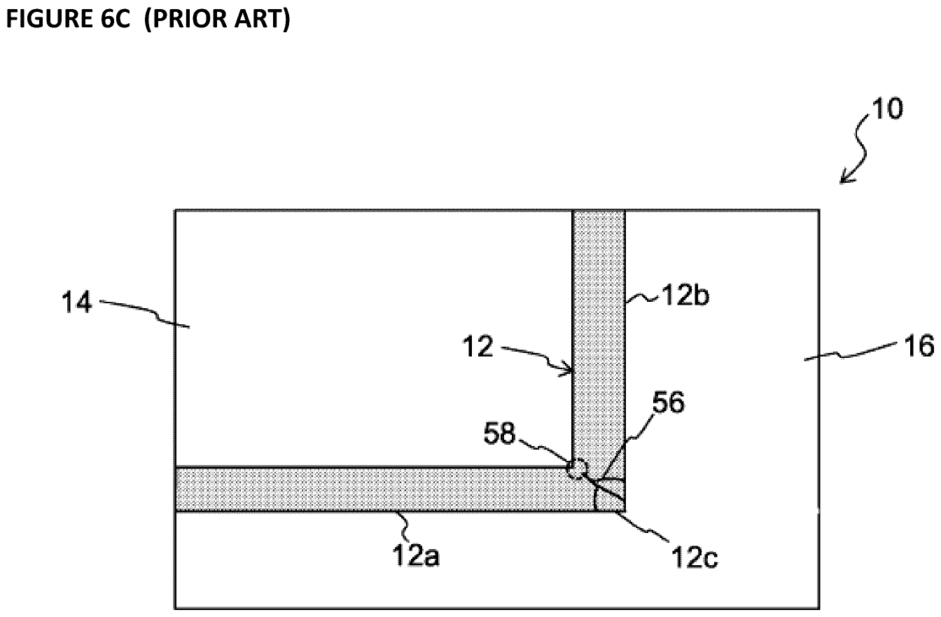

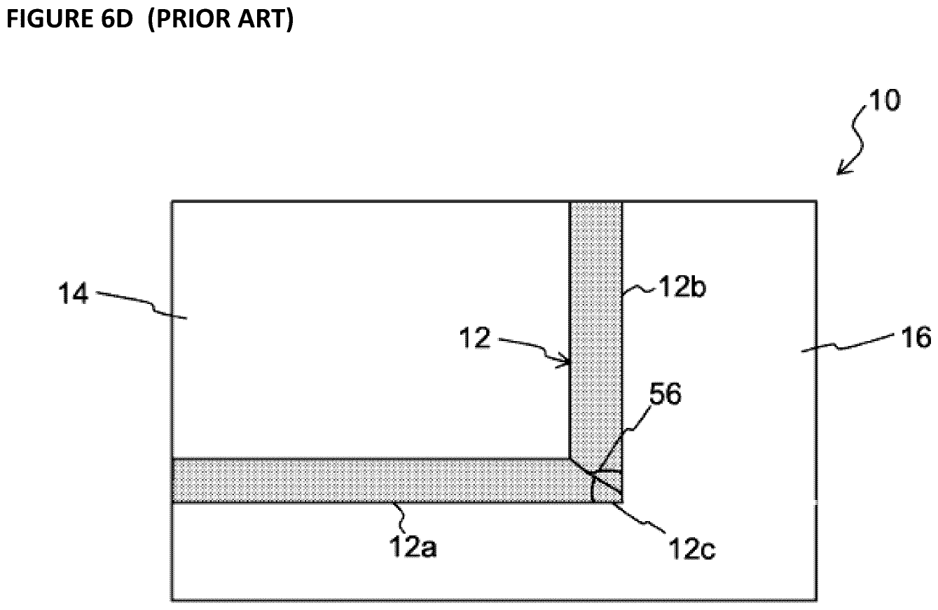

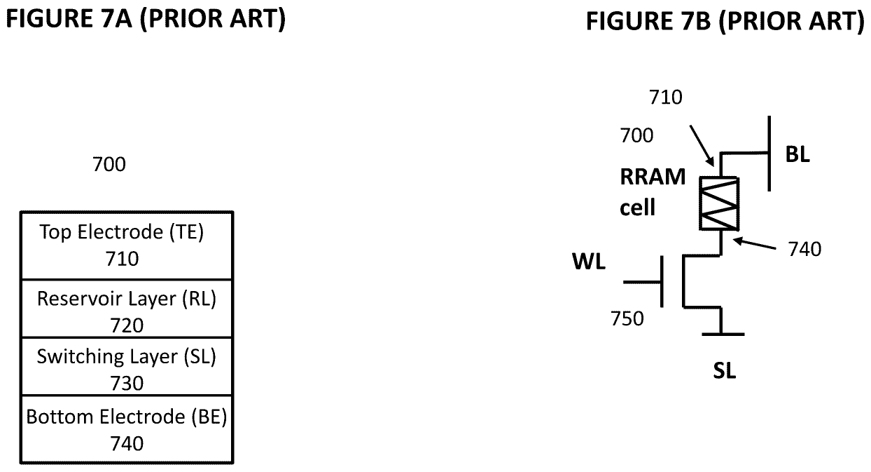

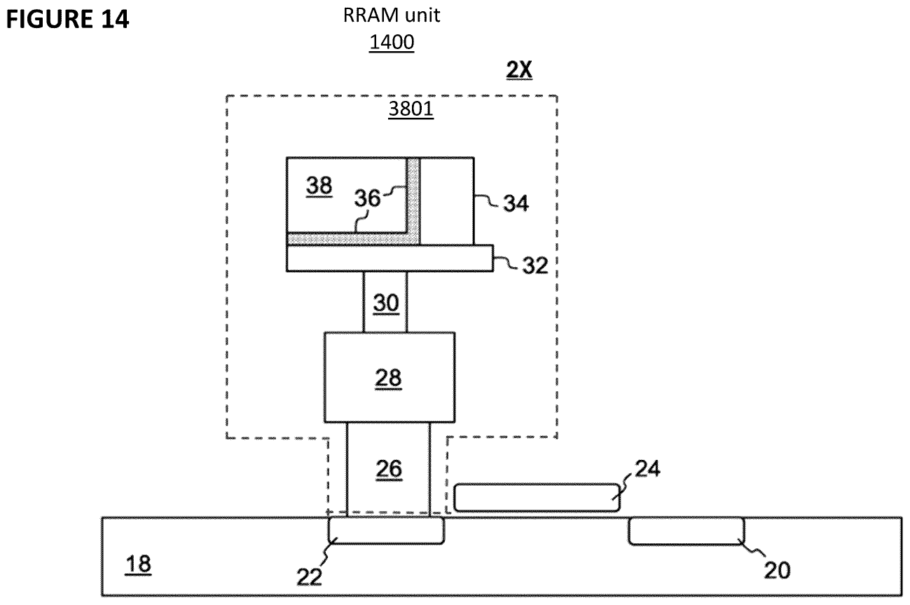

FIG. 14 shows a cross section of RRAM unit 1400, which has a 1T2R format, using the same component numbering as FIGS. 1-7. The RRAM cell is repeated twice and connected to region 22.

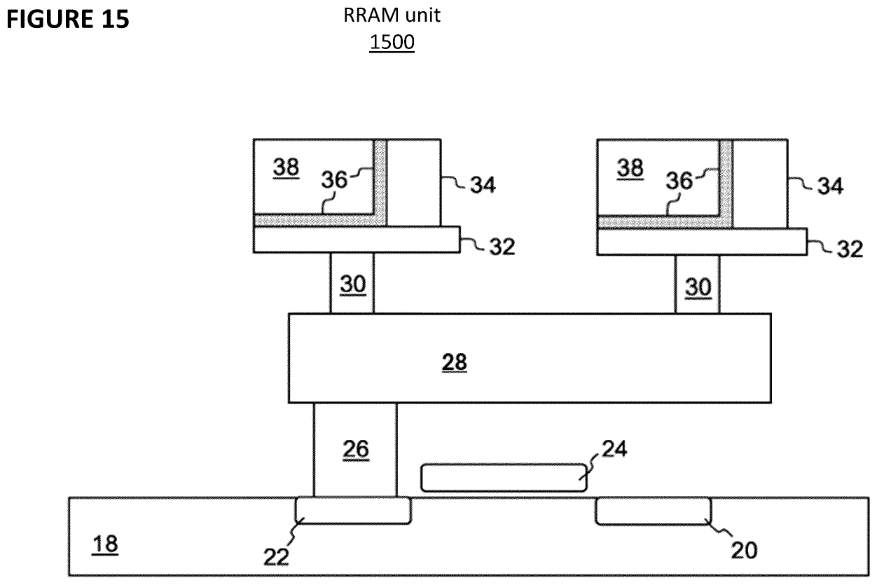

FIG. 15 shows a cross section of RRAM unit 1500, which has a 1T2R format, using the same component numbering as FIGS. 1-7. The RRAM cell is repeated twice and connected to region 28.

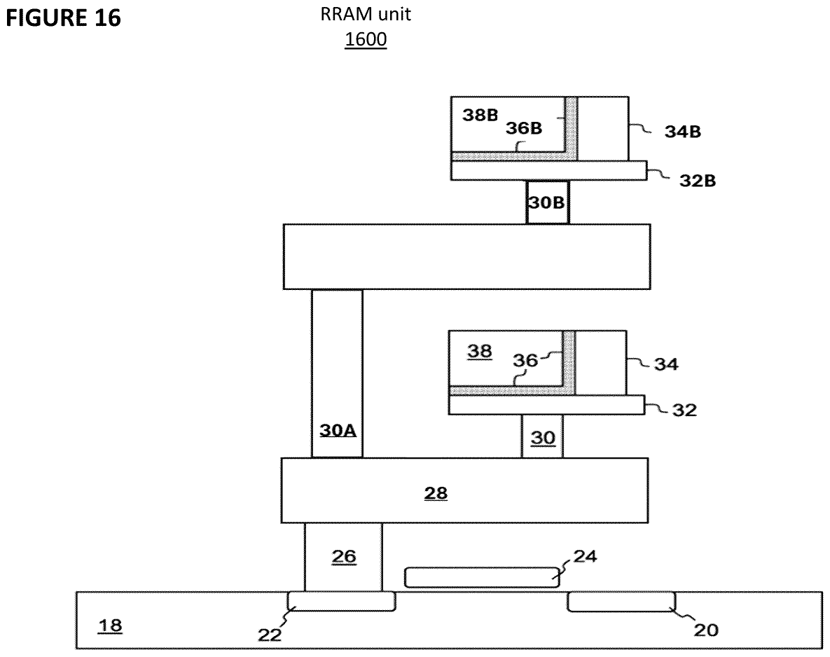

FIG. 16 shows a cross section of RRAM unit 1600, which has a 1T2R format, using the same component numbering as FIGS. 1-7. The RRAM cell is repeated twice vertically and connected to region 28.

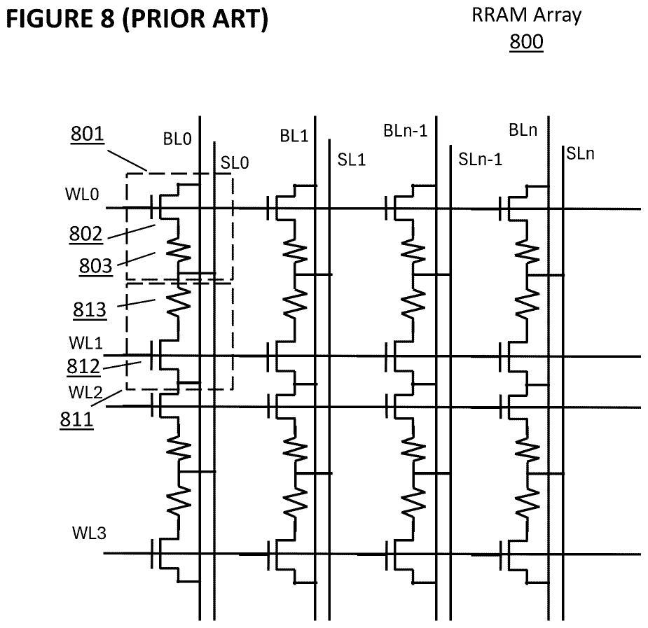

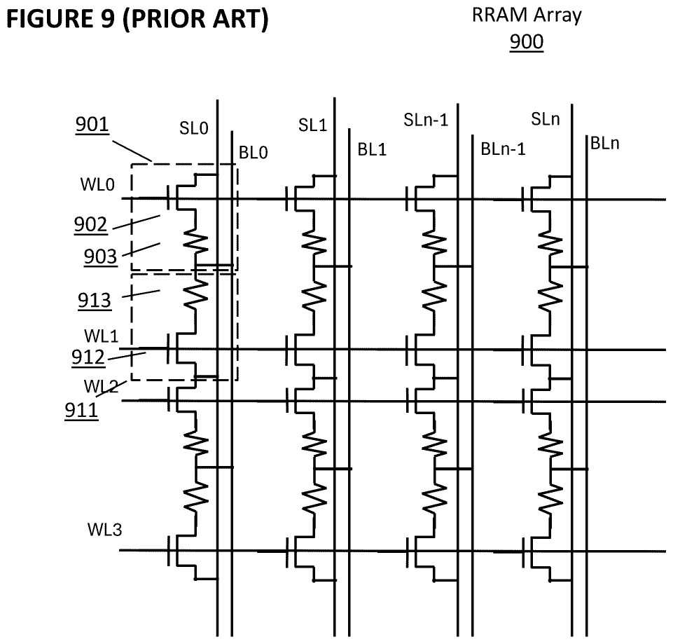

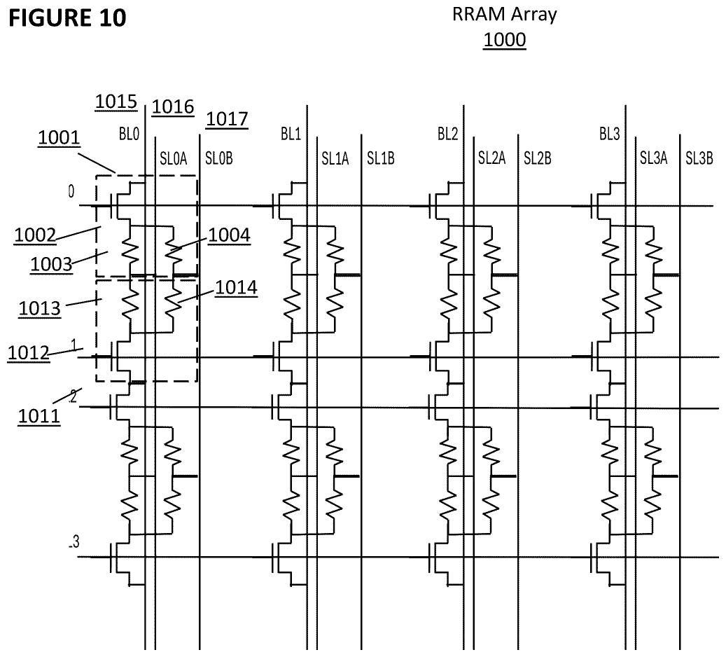

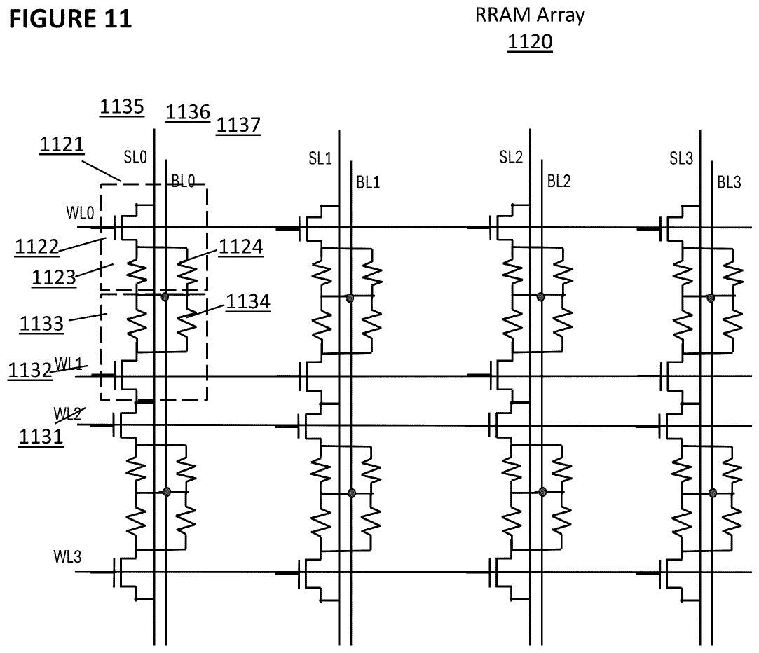

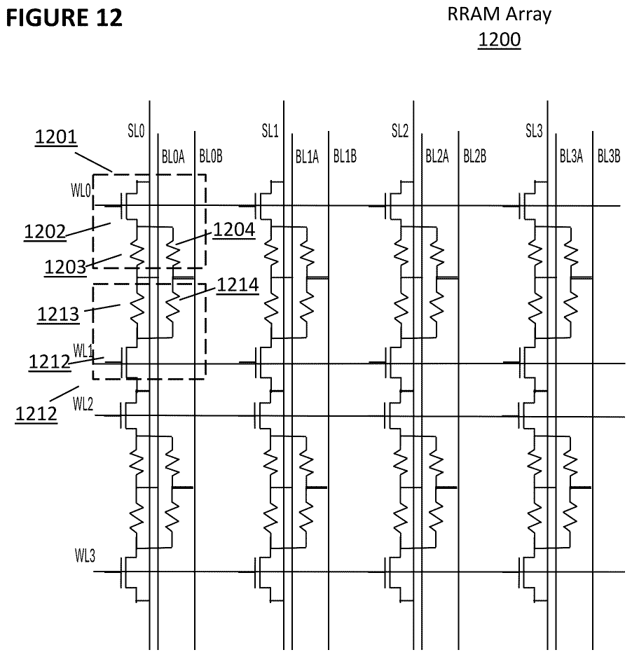

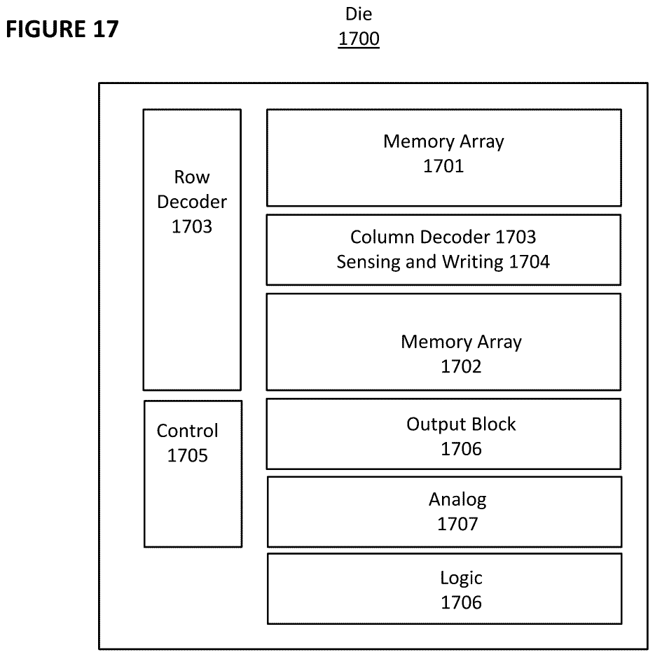

FIG. 17 depicts an example of an RRAM system that can implement the example mechanisms and techniques described herein. Die 1700 comprises: memory arrays 1701 and 1702 for storing data, where each is an instantiation of RRAM arrays 800, 900, 1000, or 1200 in FIGS. 8-11; row decoder circuit 1703 used to access the rows in memory arrays 1701 and 1702 to be read from or written to (i.e., selected for a form, a set or reset operation); column decoder circuits 1704 used to access the columns in memory arrays 1701 and 1702 to be read from or written to; sensing and writing circuit 1705 used to read data from or write (e.g., FORM/SET/RESET) data to memory arrays 1701 and 1702; read and write control logic 1706; output block 1707; read and write analog circuits 1708; and logic 1709 for providing various control functions, such as redundancy.

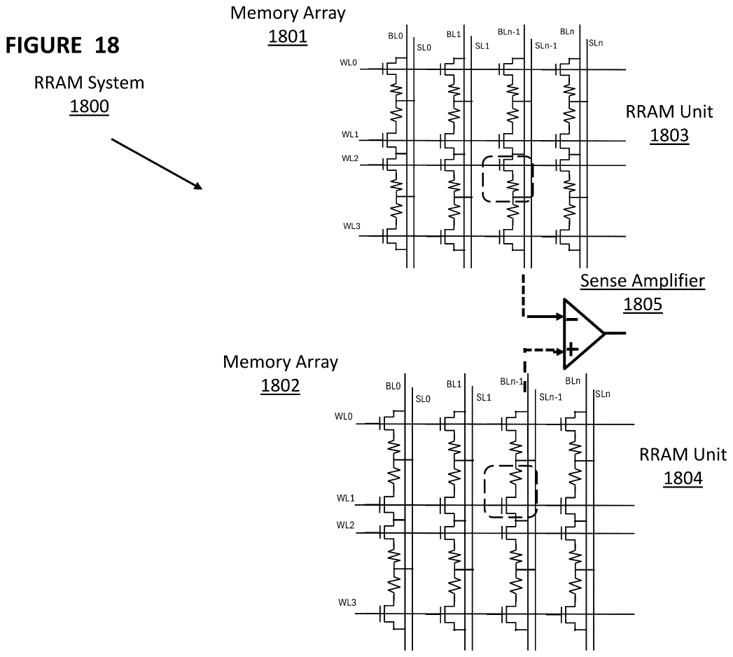

FIG. 18 depicts RRAM system 1800, which comprises memory array 1801, memory array 1802, and sense amplifier (SA) 1805. In this example, one sense amplifier is shown, but it is to be understood that RRAM system 1800 can comprise a plurality of sense amplifiers, for example, RRAM system 1800 might comprise a sense amplifier for each column. A value is stored as a differential value stored in a cell in memory array 1801 and a cell in memory array 1802 (e.g., top array bank and bottom array bank). For example, a value can be stored as a differential value (e.g., difference between a LRS and HRS) in example RRAM unit 1803 in memory array 1801 and RRAM unit 1804 in memory array 1802, wherein the value is read by sense amplifier 1805 where a first current is received from RRAM unit 1803 and provided to a first input of sense amplifier 1805 and a second current is received from RRAM unit 1804 (e.g., complementary state (LRS vs. HRS, smaller, or larger) to the first current from RRAM unit 1803) and provided to a second input of sense amplifier 1805, where the output of sense amplifier 1805 indicates the stored differential value.

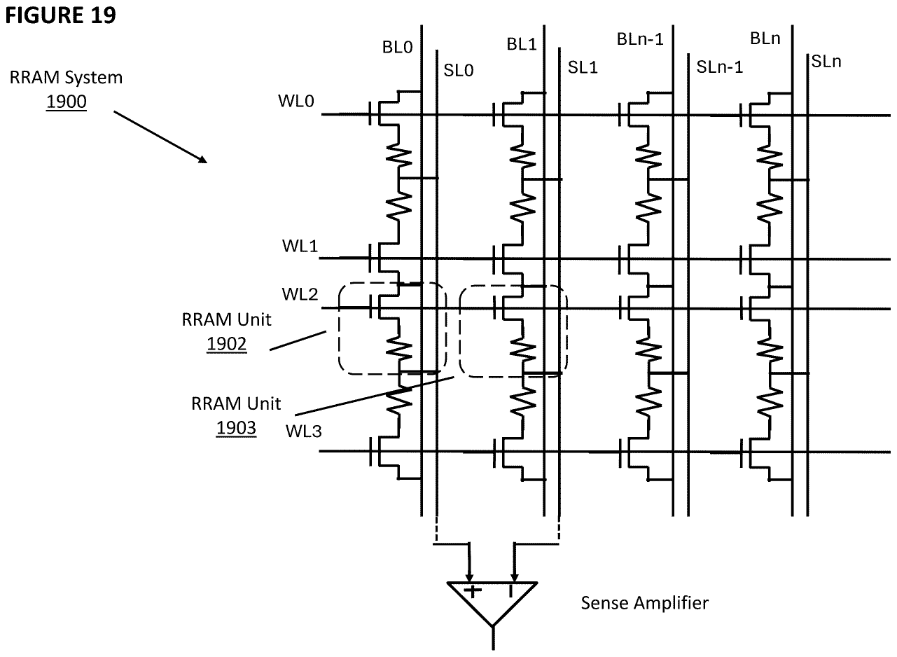

FIG. 19 depicts RRAM system 1900, which comprises memory array 1901 and sense amplifier 1904. A value is stored as a differential value (e.g., difference between a LRS and HRS) stored in a first cell in memory array 1901 and a second cell in memory array 1901 (e.g., same memory bank). The two cells are physically adjacent to each other. For example, a value can be stored as a differential value in example RRAM unit 1902 and RRAM unit 1903 in memory array 1901, wherein the value is read by sense amplifier 1904 where a first current is received from RRAM unit 1902 and provided to a first input of sense amplifier 1904 and a second current is received from RRAM unit 1903 and provided to a second input of sense amplifier 1904, where the output of sense amplifier 1904 indicates the stored differential value.

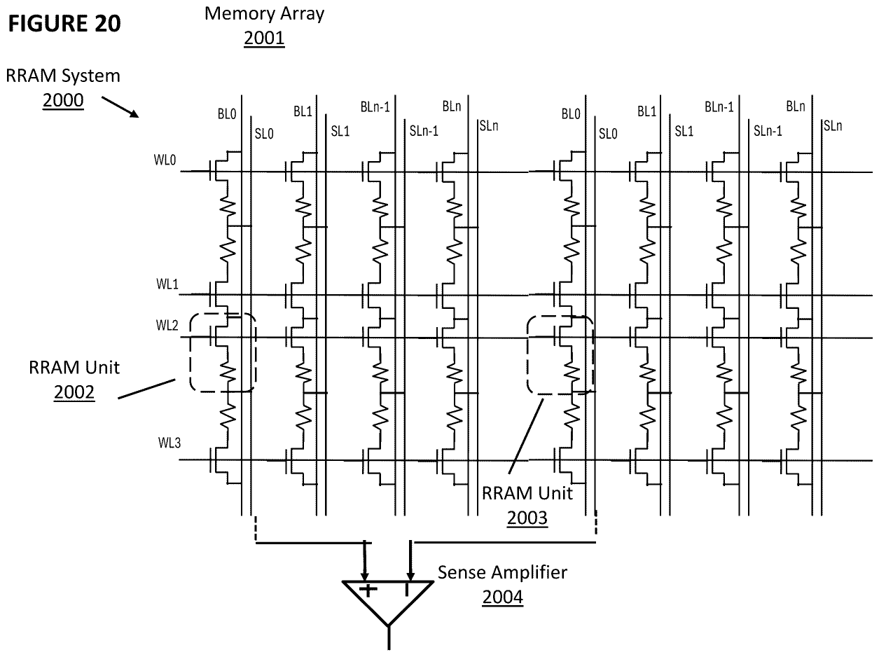

FIG. 20 depicts RRAM system 2000, which comprises memory array 2001 and sense amplifier 2004. A value is stored as a differential value stored in a first cell in memory array 2001 and a second cell in memory array 2001. The two cells are in the same memory array but not physically adjacent to each other. For example, a value can be stored as a differential value in example RRAM unit 2002 and RRAM unit 2003 in memory array 2001, wherein the value is read by sense amplifier 2004 where a first current is received from RRAM unit 2002 and provided to a first input of sense amplifier 2004 and a second current is received from RRAM unit 2003 and provided to a second input of sense amplifier 2004, where the output of sense amplifier 2004 indicates the stored value.

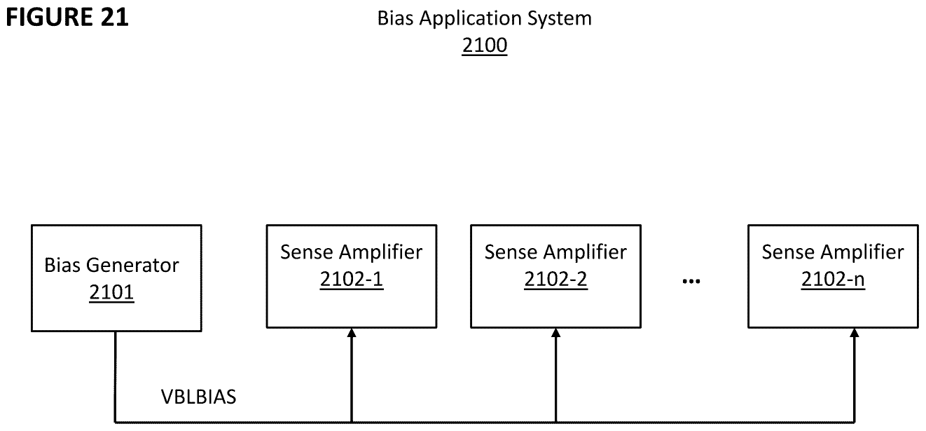

FIG. 21 depicts bias application system 2100, which comprises bias generator 2101. Bias generator 2101 applies an adaptive bias, VBLBIAS, to sense amplifiers 2102-1, 2102-2, . . . , 2102-n, where n is an integer. Bias generator 2101 optionally is a replica of other components used in the system such that the bias generated, VBLBIAS, is affected by the same conditions that affect those other components, such as temperature. The bias generator ensures the same bias condition is applied across cells in read condition irrespective of array location.

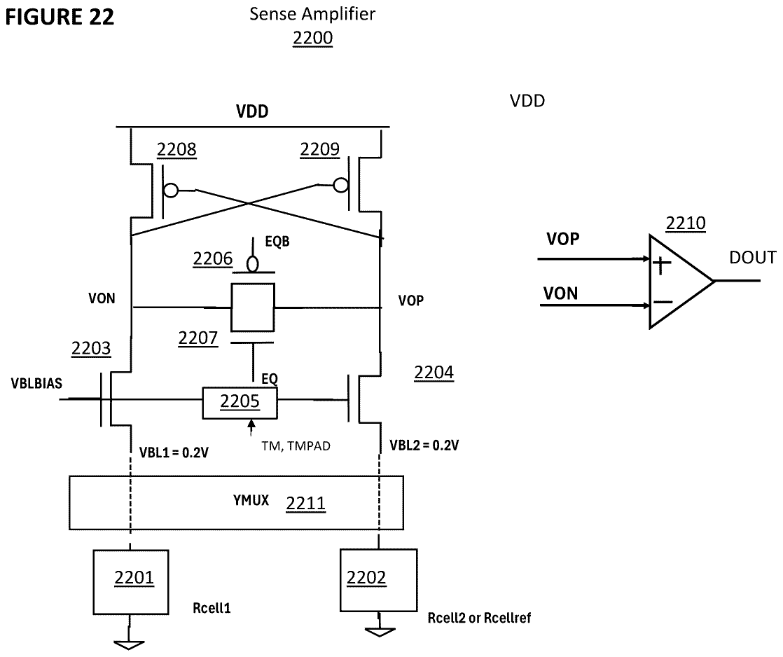

FIG. 22 depicts sense amplifier 2200, which is coupled (through decoding circuitry, not shown) to RRAM unit 2201 and RRAM unit 2202 that together store a differential value (e.g., complementary values such as one is resistively smaller or larger than the other) or a single value (e.g., RRAM unit 2201 with 2202 served as a reference unit). RRAM units 2201 and 2202 are RRAM units within a RRAM memory array such as memory arrays 1701 and 1702 in FIG. 17. Sense amplifier 2200 comprises cross coupled PMOS transistors 2208 and 2209; NMOS read bias transistors 2203, 2204, and 2207; PMOS transistor 2206; test circuit 2205 (which is used during a testing mode to directly provide a first voltage to the gate of NMOS transistor 2203 and a second voltage to the gate of NMOS transistor 2204, which can be useful, for example to test for offset); comparator 2210; and column multiplexor 2211. Prior to the sense operation, EQ is high and EQB is low, which turns on NMOS transistor 2207 and PMOS transistor 2206, causing VON and VOP to be equal. During the sense operation, EQ is pulled low and EQB is driver high, which turns off NMOS transistor 2207 and PMOS transistor 2206 such that VON and VOP are no longer connected. VBLBIAS (which can be generated by bias generator 2101 in FIG. 21) is applied to the gates of NMOS transistors 2203 and 2204, which are connected to RRAM units 2201 and 2202, respectively to ensure some bias condition is applied to both 2201 and 2202 RRAM units. VON and VOP will be pulled down by the current drawn by RRAM units 2201 and 2202. If VON is pulled below a threshold before VOP, then PMOS transistor 2209 will turn on, driving VOP high to VDD and turning off PMOS transistor 2208. If VOP is pulled below a threshold before VON, then PMOS transistor 2208 will turn on, driving VON high to VDD and turning off PMOS transistor 2209. VOP and VON are provided as inputs to comparator 2210, which generates DOUT. DOUT will be high if VOP>VON and will be low otherwise. Thus, DOUT indicates the differential value stored in RRAM units 2201 and 2202.

FIG. 22 and other sense amplifiers described herein also can be used to sense a single value from an RRAM unit instead of a differential value from two RRAM units. For example in FIG. 22, the sensing amplifier is used to sense the RRAM unit 2201 and RRAM unit 2202 is a reference RRAM unit or alternatively can be replaced with a device that provides a reference voltage or current such as a reference resistor, a reference current, or a reference tuned RRAM unit (which is tuned to a predetermined value). The reference unit in this tracks the RRAM unit in the array (i.e., location-aware) such as described in FIGS. 21 and 22. As described here for all the sense amplifier figures, the RRAM units are coupled to the sense amplifier circuits through decoding circuit(s) such as a column multiplexor, which are not shown.

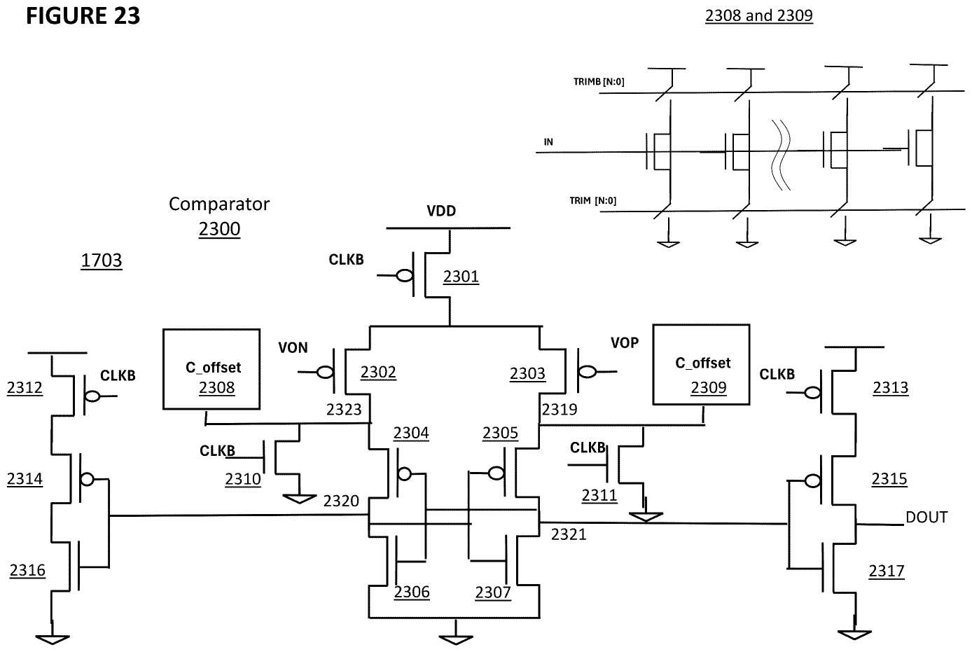

FIG. 23 depicts comparator 2300, which is an example of comparator 2210 in FIG. 22 and which receives VON and VOP and generates output DOUT. Comparator comprises PMOS transistor 2301; input pair PMOS transistors 2302 and 2303; cross coupled PMOS transistors 2304 and 2305; PMOS transistors, 2312, 2313, 2314, and 2315; cross coupled NMOS transistors 2306, and 2307; NMOS transistors 2310, 2311, 2316, and 2317; and offset circuits 2308 and 2309, which apply an offset bias, C_OFFSET, at the nodes indicated. CLKB is a clock signal. When CLKB is low, whichever of VON and VOP is low will cause PMOS transistor 2302 or 2303, respectively, to turn on, which will pull node 2318 or 2319 high. If node 2318 is high, node 2320 also will be high, and PMOS transistor 2305 will turn off and NMOS transistor 2307 will turn on, pulling node 2321 further to ground. If node 2319 is high, node 2321 also will be high, and PMOS transistor 2304 will turn off and NMOS transistor 2306 will turn on, pulling node 2320 further to ground. PMOS transistor 2315 and NMOS transistor 2317 form an inverter, and DOUT will be high if node 2321 is low and low if node 2321 is high. DOUT represents the differential value generated in response to VOP and VON, which in turn have voltages in response to the values stored in RRAM units 2201 and 2202 in FIG. 22. Offset circuit 2308 and 2309 each creates an equivalent offset voltage on the input when the offset capacitor is turned on (source and drain are coupled to ground). For each offset capacitor, the gate input is either VON or VOP, the drain/source (they are shorted together) are controlled by trimbits. If the drain/source is enabled by a trimbit to connect to ground, the capacitor (which is implemented as a NMOS transistor) is on (meaning there is effective gate capacitance) since its VGS>VT (gate to source is greater than NMOS threshold voltage). If the drain/source is enabled by a trimbit to connect to Vdd, the capacitor (which is implemented as a NMOS transistor) is off (meaning there is no gate effective capacitance) since its VGS<VT (gate to source is less than NMOS threshold voltage), This offset can be used to compensate for the offset of the whole read path shown in FIG. 17, which includes offset from the bias transistor 2203 and 2204, PMOS transistors 2208 and 2209, and the comparator itself.

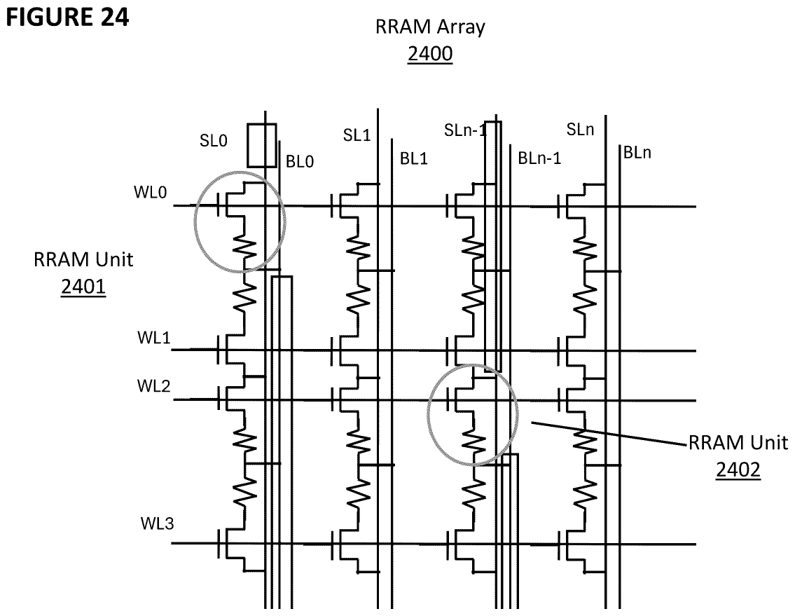

FIG. 24 depicts RRAM array 2400. In this example, RRAM unit 2401 and RRAM unit 2402 form a differential pair. However, an offset will occur because the parasitic resistances generated by the interconnect source lines and bit lines will differ for RRAM unit 2401 and RRAM unit 2402 because the amount of metal in the source line SL0 between RRAM unit 2401 and the source line driver (not shown) and in the source line SLn−1 between RRAM unit 2402 and the source line driver (not shown) are different, and the amount of metal in the bit line BL0 between RRAM unit 2401 and the bit line driver or sense amplifier (not shown) and between the bit line BLn−1 and RRAM unit 2402 and the bit line driver or sense amplifier (not shown) are different. Each of these differences results in different resistances. When voltages are applied by the source line driver or bit line driver, a different voltage drop will occur on the various lines such that RRAM units 2401 and 2402 receive different voltages when the same voltage was intended.

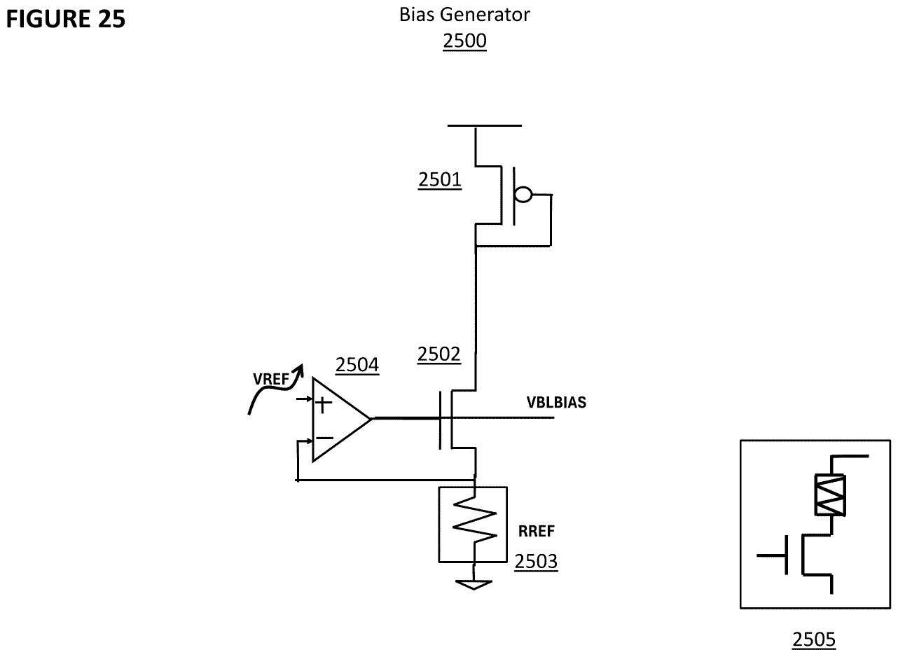

FIG. 25 depicts bias generator 2500 which is used to generate a bias on the read bias transistor 2203 and 2203 in FIG. 22, VBLBIAS, that can be applied to compensate for offsets such as the offset from the BL or SL interconnect resistance described above with reference to FIG. 25. The offset compensation is from adjusting VREF voltage to track the RRAM BL and SL resistance. Bias generator 2500 is an example implementation of bias generator 2101 in FIG. 21. Bias generator 2500 comprises PMOS load transistor 2501 (which can be a NMOS load, a resister load, or a current load), NMOS read master bias transistor 2502, resistance unit 2503 (which can be a variable resistor or an RRAM resistor or a RRAM unit 2505), and operational amplifier 2504. NMOS master bias transistor 2502 tracks the read bias transistor 2203 and 2204 so that VGS (gate to source) of these devices are approximately the same to ensure the read voltage, e.g., VBL, on the read RRAM units are the same. The output of operational amplifier controls the gate of NMOS transistor 2502. The inverting node of operation amplifier 2504 receives the voltage at the first terminal of resistance unit 2503. The second terminal of resistance unit 2503 is coupled to ground. The non-inverting node of the operation amplifier 2504 receives the reference voltage VREF. Due the feedback loop of the operational amplifier 2504, the first terminal of the resistance is equal to the reference voltage VREF. VBLBIAS is then used as a (column) read bias voltage for the bias transistors in the sensing circuitry such as in FIG. 17.

The VREF voltage is trimmable to adjust the read voltage imposed on the read RRAM units. VREF can be used to adjust the voltage on the VBL (read bias voltage on the RRAM units) depending on their location in the array to compensate for the IR drop along the array metal lines.

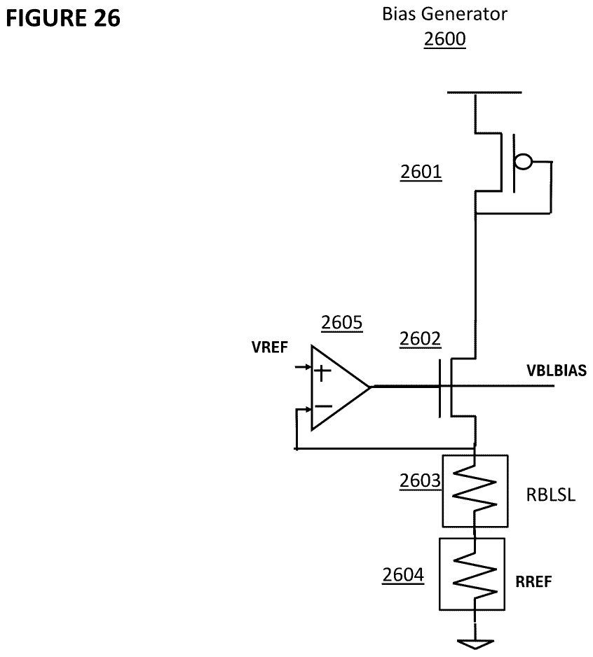

FIG. 26 depicts bias generator 2600 which is used to generate a bias, VBLBIAS, that can be applied to compensate for offsets such as the offset described above with reference to FIG. 24. Bias generator 2600 is an example implementation of bias generator 2101 in FIG. 21. Bias generator 2600 comprises PMOS load transistor 2601 (which can be a NMOS load, a resister load, or a current load), NMOS transistor 2602, resistor 2603 (which is intended to mimic the resistance of a bit line and a source line for a particular column of cells in FIG. 21), resistance unit 2604 (which can be a variable resistor or an RRAM resistor or a RRAM unit), and operational amplifier 2605. The output of operational amplifier 2605 controls the gate of NMOS transistor 2602. The inverting node of operation amplifier 2605 receives the voltage at the first terminal of resistor 2603. The second terminal of resistor 2603 is coupled to the first terminal of resistance unit 2604, and the second terminal of resistance unit 2604 is coupled to ground. The non-inverting node of operational amplifier 2605 receives a variable voltage VREF. Due to the feedback loop of the operational amplifier 2605, the first terminal of the resistance is equal to the reference voltage VREF. t. NMOS master bias transistor 2602 tracks the read bias transistor 2203 and 2204 in FIG. 17 so that VGS (gate to source) of these devices are approximately the same to ensure the read voltage, e.g., VBL, on the read RRAM units are the same. VBLBIAS is then used as a (column) read bias voltage for the bias transistors in the sensing circuitry such as in FIG. 17.

RBLSL is used in series with a RRAM unit (2604). RBLSL+RREF (RRAM unit) in FIG. 26 is approximately the same as RSL+RBL+resistance of RRAM unit in FIG. 24.

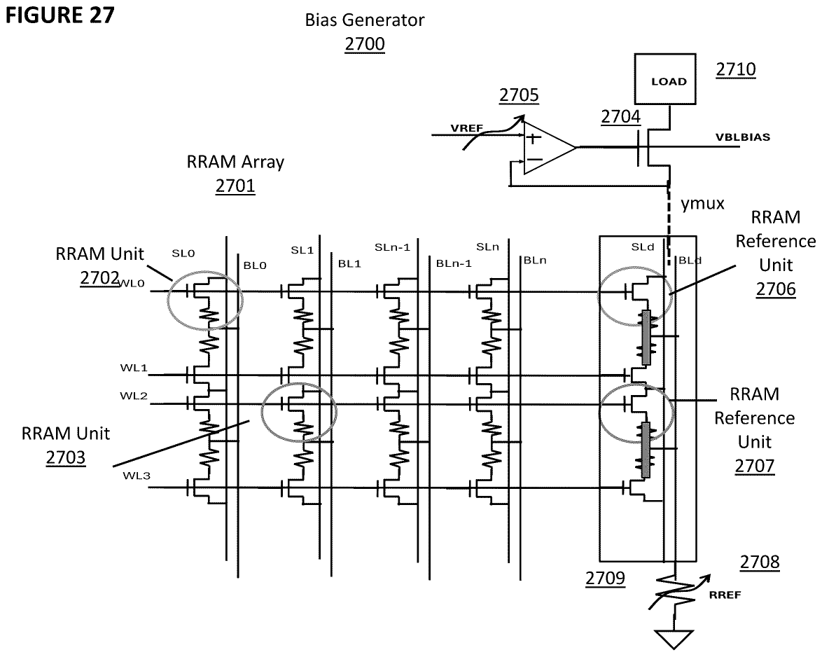

FIG. 27 depicts bias generator 2700 which is used to generate a bias, VBLBIAS, that can be applied to compensate for offsets such as the offset described above with reference to FIG. 24. Bias generator 2700 is an example implementation of bias generator 2101 in FIG. 21. Bias generator 2700 is coupled to RRAM array 2701. In this example, RRAM unit 2702 and RRAM unit 2703 store a value and will be the subject of an operation. For storing a differential value another RRAM unit (with similar row and column location) together with RRAM unit 2702 and another RRAM unit (with similar row and column location) with RRAM unit 2703 are used to store the differential value. Bias generator 2700 will generate a bias voltage that tracks the bit line resistance and source line resistance associated with each of RRAM units 2702 and 2703. Bias generator 2700 comprises a column 2709 of RRAM cells that are of the same structure as a column of RRAM cells in RRAM array 2701. Optionally, column 2709 can be a column in RRAM array 2701. RRAM reference units 2706 and 2707 are selected and enabled because they are in the same vertical locations within column 2709 as RRAM units 2702 and 2703, respectively, within their respective columns. Bias generator 2700 further comprises load 2710 (e.g., PMOS, NMOS, Resister, Current source), NMOS master read bias transistor 2704, operational amplifier 2705, and variable reference unit 2708 (e.g., a trimmable resistor, current source, reference RRAM unit(s)). The output of operational amplifier 2705 controls the gate of NMOS transistor 2704. The inverting node of operation amplifier 2705 receives the voltage at the top of column 2709. The non-inverting node of operational amplifier 2705 receives a variable voltage VREF. VBLBIAS is then used as a bias voltage for the read bias transistor in the sense amplifier to impose the VREF voltage on the read RRAM units.

In one example, the RRAM cells in the RRAM reference units (e.g., 2706, 2707) are shorted by interconnect.

In another example, the RRAM cells in the RRAM reference units (e.g., 2706, 2707) are used as reference unit, in this case these reference RRAM cells are tuned to a trip point target level. In this case the RRAM cells can be a combination of multiple reference cells such as a LRS cell and another LRS cell, or a combination of LRS cells and HRS cells. In this case reference unit 2708 may not be needed.

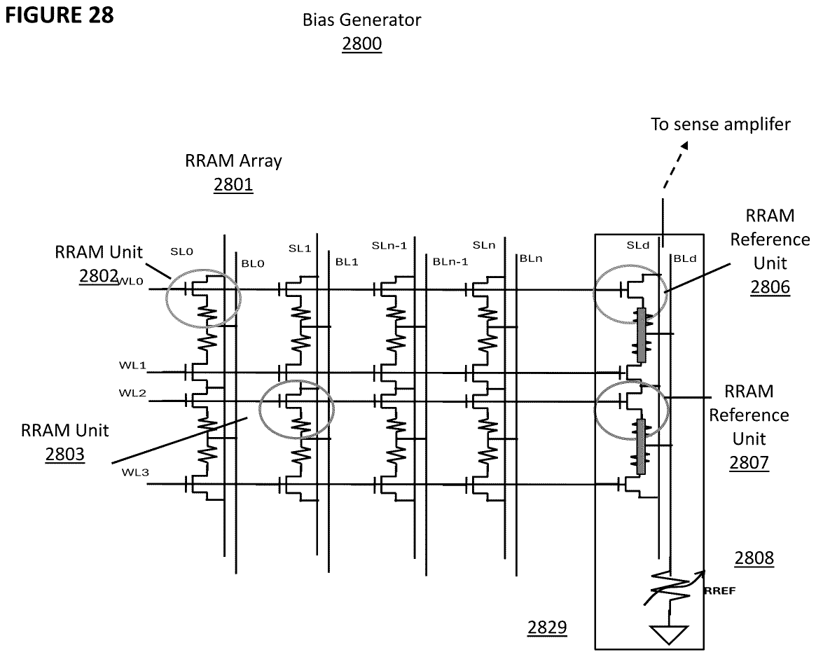

FIG. 28 depicts bias generator 2800 which is similar to the bias generator 2700 except it does not contain an operational amplifier and load circuit. Bias generator 2800 is an example implementation of bias generator 2101 in FIG. 21. Bias generator 2800 is coupled to RRAM array 2801. In this example, RRAM unit 2802 and RRAM unit 2803 store a value and will be the subject of an operation. Bias generator 2800 comprises a column 2829 of RRAM cells that are of the same structure as a column of RRAM cells in RRAM array 2801. Optionally, column 2829 can be a column in RRAM array 2801. Column 2829 further comprises variable resistor 2808. RRAM reference units 2806 and 2807 are selected and enabled because they are in the same vertical locations within column 2829 as RRAM units 2802 and 2803, respectively, within their respective columns. The array column 2829 and example RRAM reference units 2806 and 2807 are used to provide reference units to the sense amplifier. This is used in the case of sense amplifier is used to sense a single value from a RRAM unit, in contrast to the situation where a sense amplifier senses a differential value from two RRAM units.

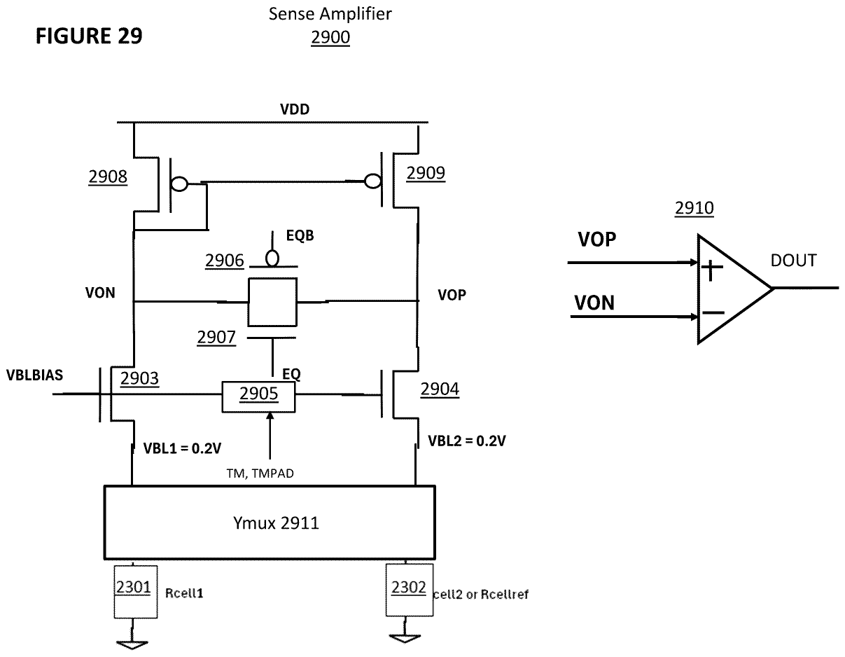

FIG. 29 depicts sense amplifier 2900, which is coupled to RRAM unit 2901 and RRAM unit 2902 that together store a differential value or a single value. RRAM units 2901 and 2902 are RRAM units within a RRAM memory array such as memory arrays 1701 and 1702 in FIG. 17. Sense amplifier 2900 comprises a current mirror formed by PMOS transistors 2908 and 2909; NMOS transistors 2903, 2904, and 2907; PMOS transistor 2906; test circuit 2905 (similar to test circuit 2205 in FIG. 22); comparator 2910; and column multiplexor 2911. Instead of the cross coupled PMOS 2208 and 2209 in FIG. 17, the PMOS load 2908 and 2908 are connected as a current mirror with PMOS 2908 diode connected (gate and drain shorted together). Prior to the sense operation, EQ is high and EQB is low, which turns on NMOS transistor 2907 and PMOS transistor 2906, causing VON and VOP to be equal. During the sense operation, EQ is pulled low and EQB is driver high, which turns off NMOS transistor 2907 and PMOS transistor 2906 such that VON and VOP are no longer connected. VBLBIAS (which can be generated by bias generator 2101 in FIG. 21) is applied to the gates of NMOS transistors 2903 and 2904, which are connected to RRAM units 2901 and 2902, respectively. The current mirror formed by PMOS transistors 2908 and 2909 causes the current from the RRAM unit 2901 to pull up node VOP against the current from RRAM unit 2902. The voltage VOP therefore will depend on the resistances of RRAM units 2901 versus 2902. VOP and VON are provided as inputs to comparator 2910, which generates DOUT. DOUT will be high if VOP>VON and will be low otherwise. Thus, DOUT indicates the differential value stored in RRAM units 2901 and 2902.

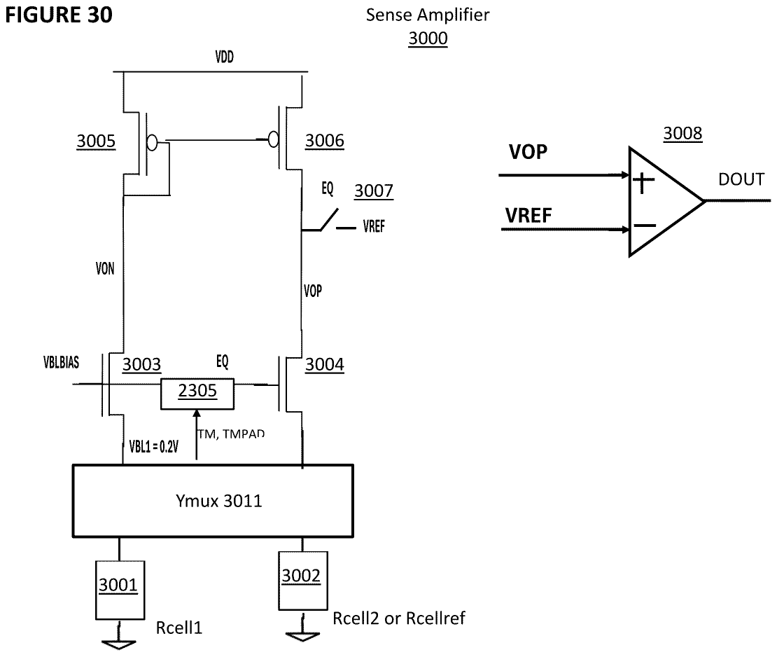

FIG. 30 depicts sense amplifier 3000 which is similar the sense amplifier 2900 in FIG. 29. Sense amplifier 3000 is coupled to RRAM unit 3001 and RRAM unit 3002 that together store a differential value or a single value. RRAM units 3001 and 3002 are RRAM units within a RRAM memory array such as memory arrays 1701 and 1702 in FIG. 17. Sense amplifier 3000 comprises a current mirror formed by PMOS transistors 3005 and 3005; NMOS transistors 3003 and 3004; test circuit 3007 (similar to test circuit 2205 in FIG. 22); switch 3008; comparator 3009; and column multiplexor 3010. Comparator 3009 compares VOP against a reference voltage VREF.

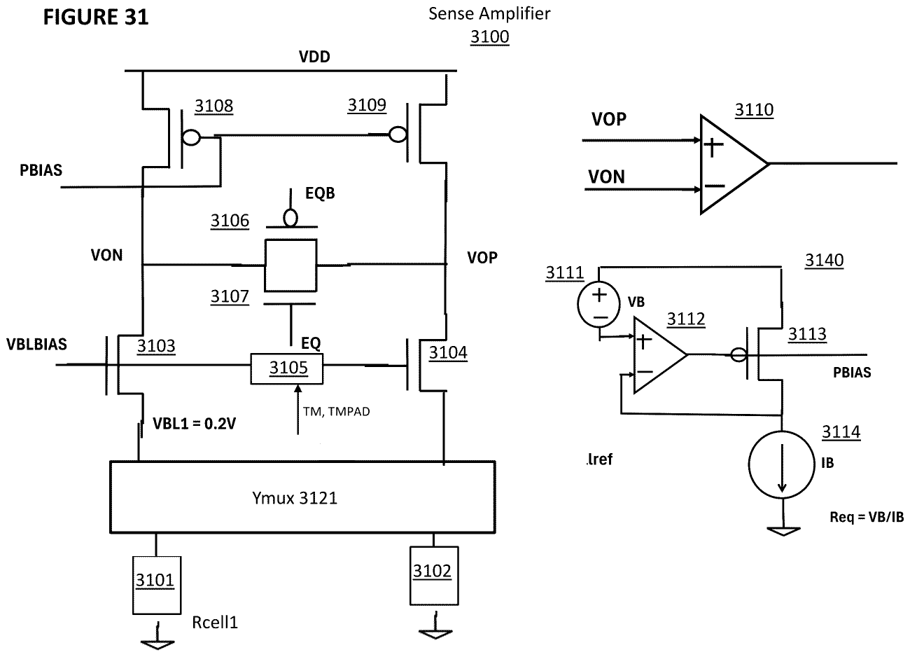

FIG. 31 depicts sense amplifier 3100, which is coupled to RRAM unit 3101 and RRAM unit 3102 that together store a differential value or a single value. RRAM units 3101 and 3102 are RRAM units within a RRAM memory array such as memory arrays 1701 and 1702 in FIG. 17. Sense amplifier 3100 is identical to sense amplifier 2900 in FIG. 29 except that a bias, PBIAS, is applied to the gates of PMOS transistors 3108 and 3109. The PBIAS is controlled by a resistance replica loop 3140 to impose a fixed resistance on the PMOS transistor 3108 and 3109. Sense amplifier 3100 comprises a current mirror formed by PMOS transistors 3108 and 3109; NMOS transistors 3103, 3104, and 3107; PMOS transistor 3106; test circuit 3105 (similar to test circuit 2205 in FIG. 22); comparator 3110; and column multiplexor 3121. Prior to the sense operation, EQ is high and EQB is low, which turns on NMOS transistor 3107 and PMOS transistor 3106, causing VON and VOP to be equal. During the sense operation, EQ is pulled low and EQB is driver high, which turns off NMOS transistor 3107 and PMOS transistor 3106 such that VON and VOP are no longer connected. VBLBIAS (which can be generated by bias generator 2101 in FIG. 21) is applied to the gates of NMOS transistors 3103 and 3104, which are coupled to RRAM units 3101 and 3102, respectively. The current mirror formed by PMOS transistors 3108 and 3109 causes the same current to be drawn by RRAM unit 3101 and RRAM unit 3102. The voltages of VON and VOP therefore will then move depending on the currents proportional to the resistances of RRAM units 3101 and 3102. VOP and VON are provided as inputs to comparator 3110, which generates DOUT. DOUT will be high if VOP>VON and will be low otherwise. Thus, DOUT indicates the differential value stored in RRAM units 3101 and 3102.

The bias voltage, PBIAS, is generated by the circuit formed by voltage source VB 3111, operational amplifier 3112, PMOS transistor 3113, and variable current source IBIAS 3114. The equivalent resistance created by the PMOS 3113 Req=VB/IBIAS. Since same voltages are imposed in the PMOS load transistor 3108 and 3109, both these two transistors having same equivalent resistance.

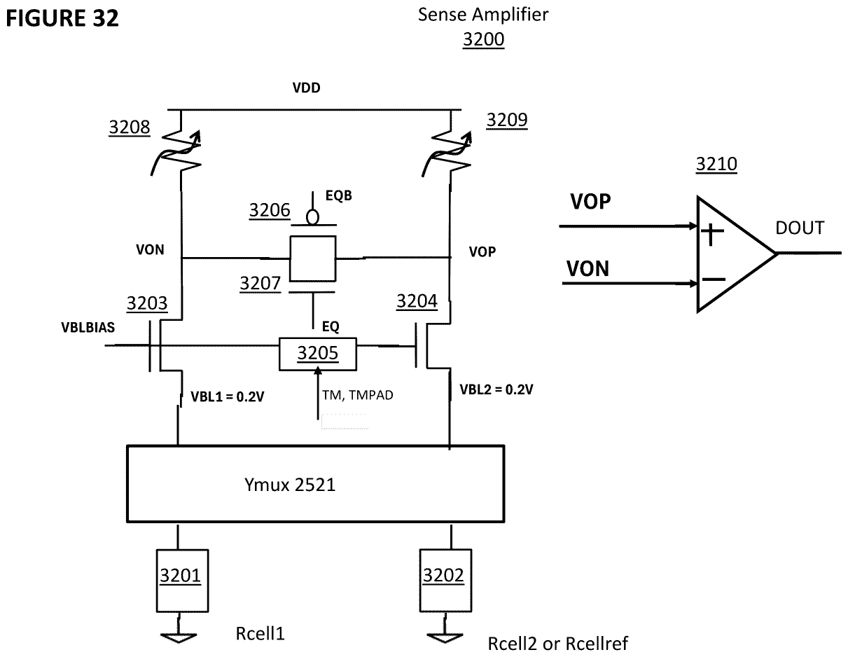

FIG. 32 depicts sense amplifier 3200, which is coupled to RRAM unit 3201 and RRAM unit 3202 that together store a differential value or a single value. RRAM units 3201 and 3202 are RRAM units within a RRAM memory array such as memory arrays 1701 and 1702 in FIG. 17. The sense amplifier is similar the sense amplifier 2200 in FIG. 22 except instead of PMOS load now it has trimmable resistor load 3208 and 3209.

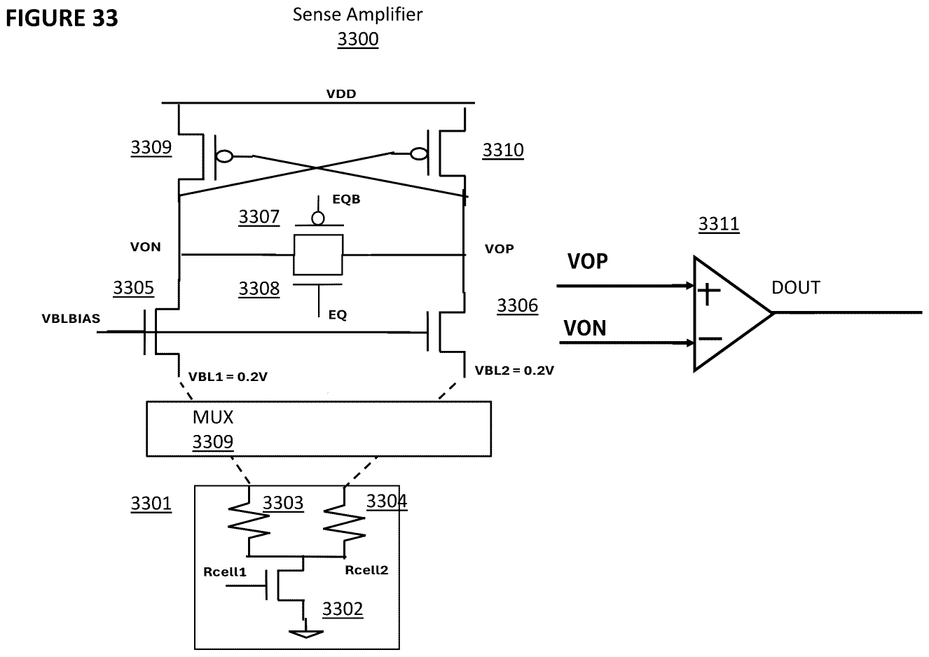

FIG. 33 depicts sense amplifier 3300, which is similar the sense amplifier 2200 in FIG. 22, except now it is coupled to differential RRAM 1T2R unit 3301, which comprises select transistor 3302 and RRAM cells 3303 and 3304 that together store a differential value. RRAM unit 3301 is a RRAM unit within a RRAM memory array such as memory arrays 1701 and 1702 in FIG. 17. DOUT indicates the differential value stored in RRAM cells 3303 and 3304. For example, RRAM cell 3303 can be LRS ad RRAM cell 3304 can be a HRS or vice versa. Or the RRAM cell 3303 can has a higher resistance than that if the RRAM cell 3304.

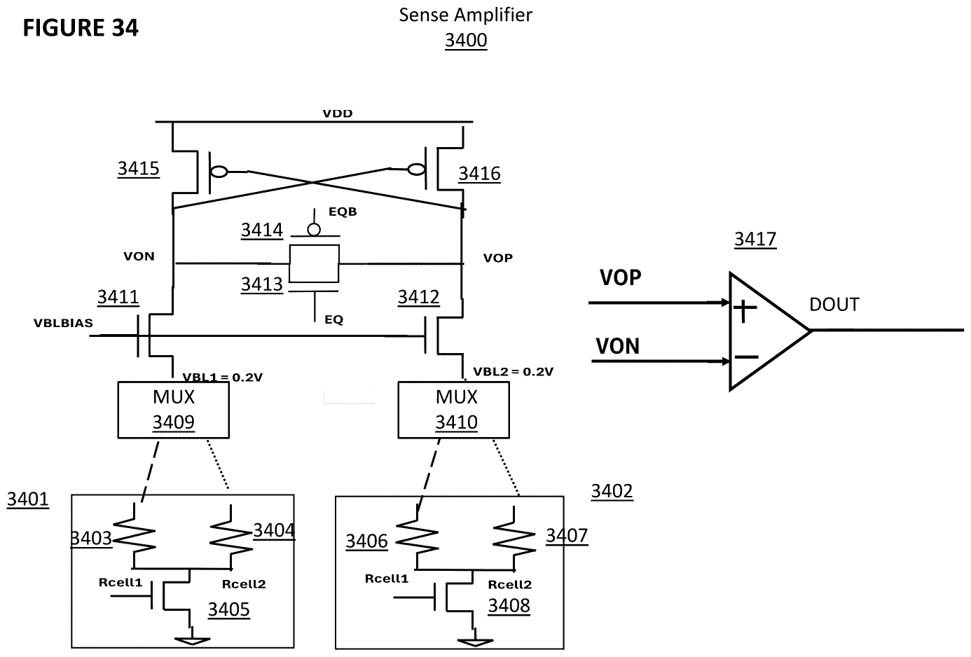

FIG. 34 depicts sense amplifier 3400, which is coupled to differential RRAM unit 3401 and differential RRAM units 3402. RRAM units 3401 and 3402 are RRAM units within a RRAM memory array such as memory arrays 1701 and 1702 in FIG. 17. RRAM unit 3401 comprises select transistor 3405 and RRAM cells 3403 and 3404, where one of the RRAM cells is selected for an operation by multiplexor 3409. RRAM unit 3402 comprises select transistor 3408 and RRAM cells 3406 and 3407, where one of the RRAM cells is selected for an operation by multiplexor 3410. The selected cell from among RRAM cells 3403 and 3404 and the selected cell from among RRAM cells 3406 and 3407 together store a differential value. Sense amplifier 3400 behaves similarly to that of the sense amplifier 2200 in FIG. 17. DOUT indicates the differential value stored in the selected RRAM cell among RRAM cells 3403 and 3404 and the selected RRAM cell among RRAM cells 3406 and 3407.

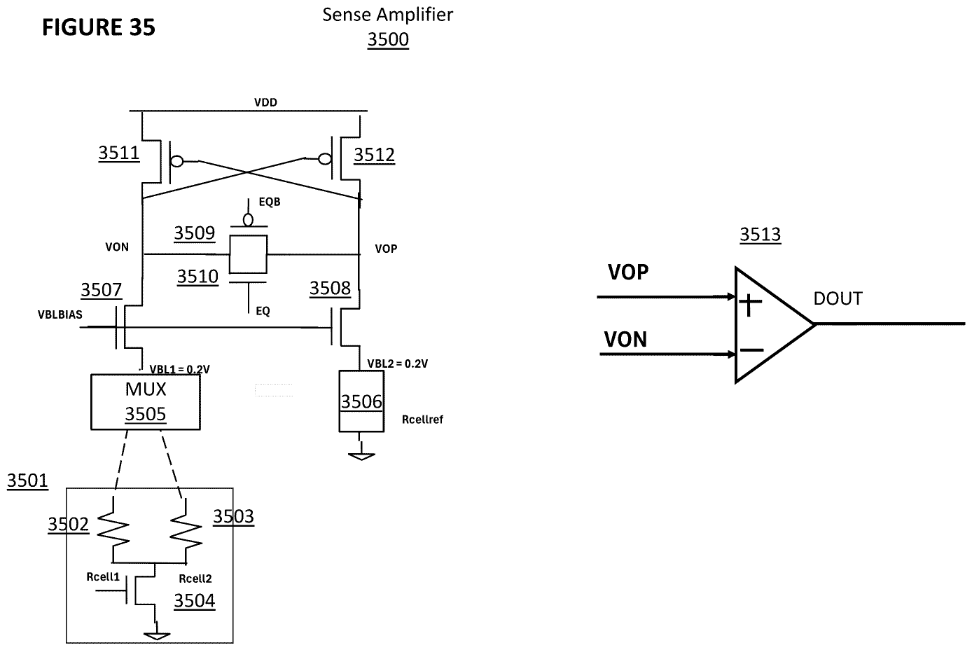

FIG. 35 depicts sense amplifier 3500, which is coupled to differential RRAM unit 3501 and reference unit 3506. RRAM unit 3501 and optionally reference unit 3506 are RRAM units within a RRAM memory array such as memory arrays 1701 and 1702 in FIG. 17. RRAM unit 3501 comprises select transistor 3504 and RRAM cells 3502 and 3503, where one of the RRAM cells is selected for an operation by multiplexor 3505. Reference unit 3506 can comprise a select transistor and a tuned RRAM cell (meaning have a predetermined resistance value). The reference unit 3506 can be a resister, a current source or a sized biased transistor. The selected cell from among RRAM cells 3502 and 3503 and RRAM unit 3506 together store a single value. DOUT indicates the value stored in the selected RRAM cell among RRAM cells 3502 and 3503 and RRAM unit 3506 whether it is LRS or a HRS state cell for example.

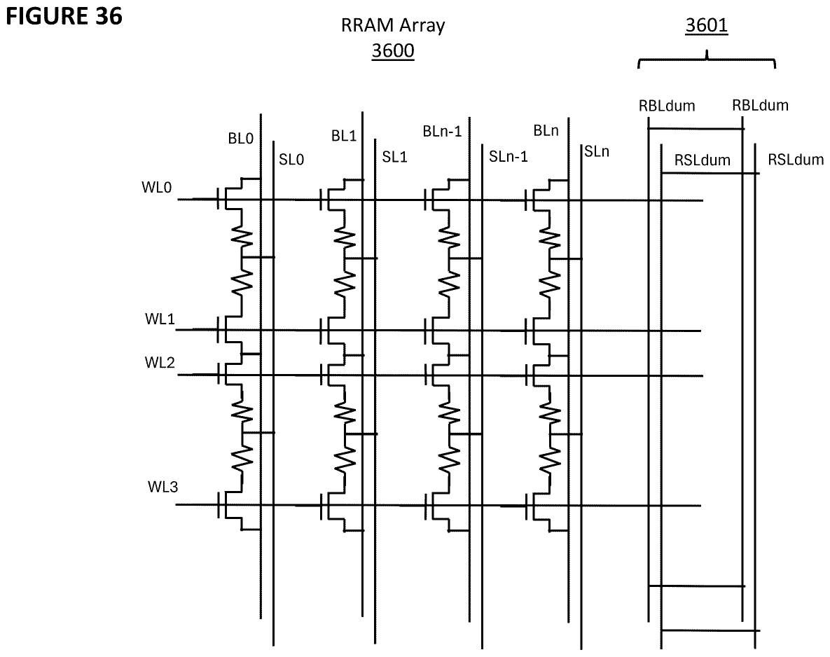

FIG. 36 depicts RRAM array 3600, which comprises one or more dummy bit lines and one or more dummy source lines 3601. The dummy BL line or SL line are such as to be used as replica bitline and source line resistance for the bias generator in FIG. 21 to ensure the bias read voltages to be approximately the same for all the RRAM cells.

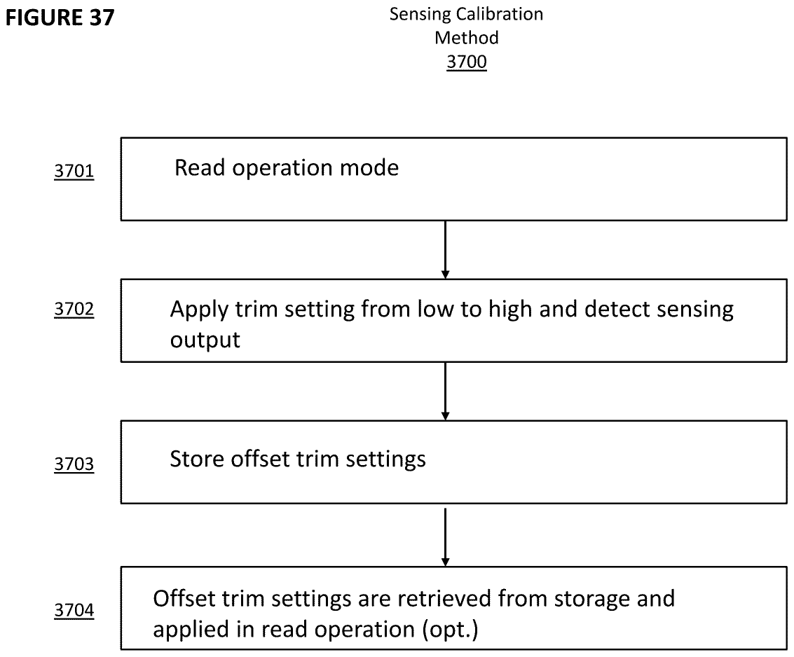

FIG. 37 depicts sensing calibration method 3700. The RRAM array enters read operation mode (3701). Trim settings are applied from low to high and the sensing output is detected (3702). The offset trim settings can be identified, for example, when a comparator output changes from low to high or high to low. The offset trim settings are stored (3703). Optionally, the stored offset trim settings are retrieved and applied in a subsequent read operation (3704).

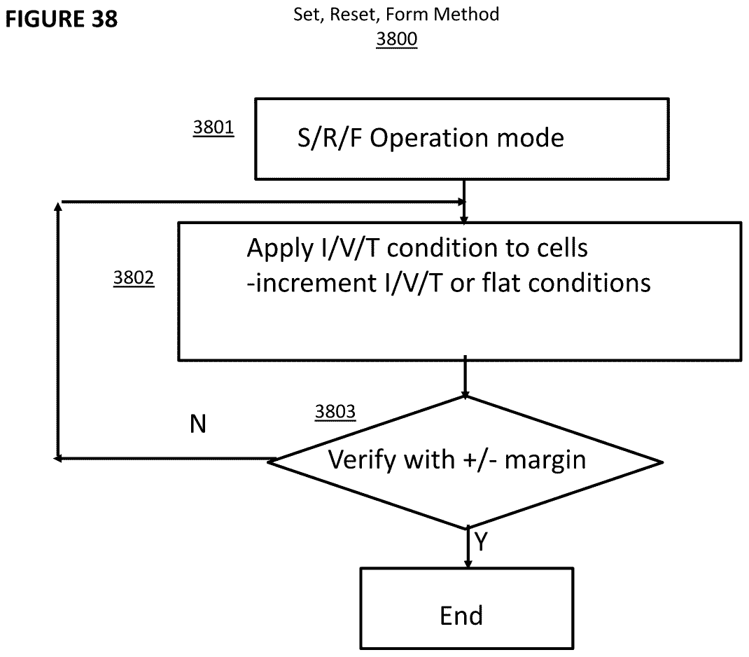

FIG. 38 depicts set, reset, form method 3800. The RRAM array enters set, reset, form operation mode (3801). One or more of current, voltage, and temperature conditions are applied to cells, and those parameters are incremented or remain flat (3802). The stored values are verified and it is determined whether the stored values are within an acceptable threshold window (+/−margin) (3803). If yes, the method ends. If no, the method repeats operations 3802 and 3803.

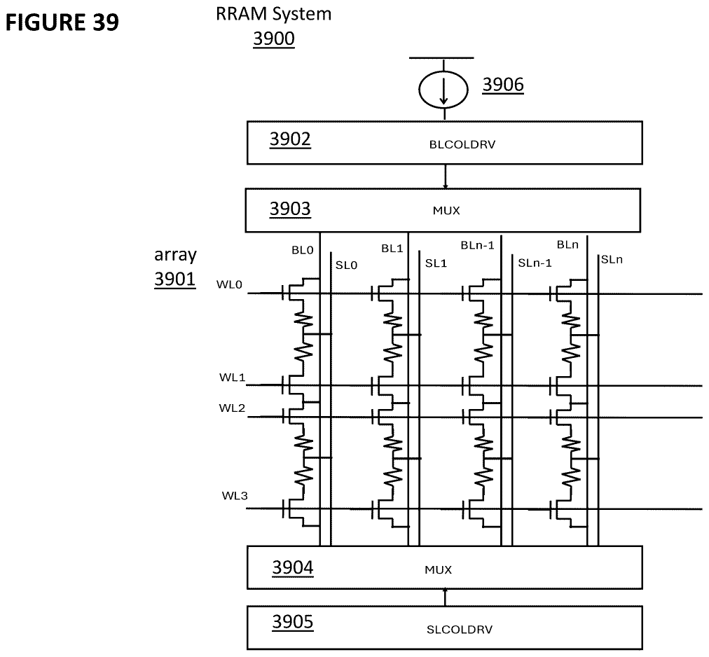

FIG. 39 depicts RRAM system 3900, which comprises RRAM array 3901, bit line column driver 3902, multiplexor 3903, multiplexor 3904, source line column driver 3905, and current limiter 3906. Current limiter 3906 limits the amount of current drawn or applied by bit line column driver 3902 and source line column driver 3905 to provide protection in the event a short circuit occurs and to control the temperature of RRAM system 3900.

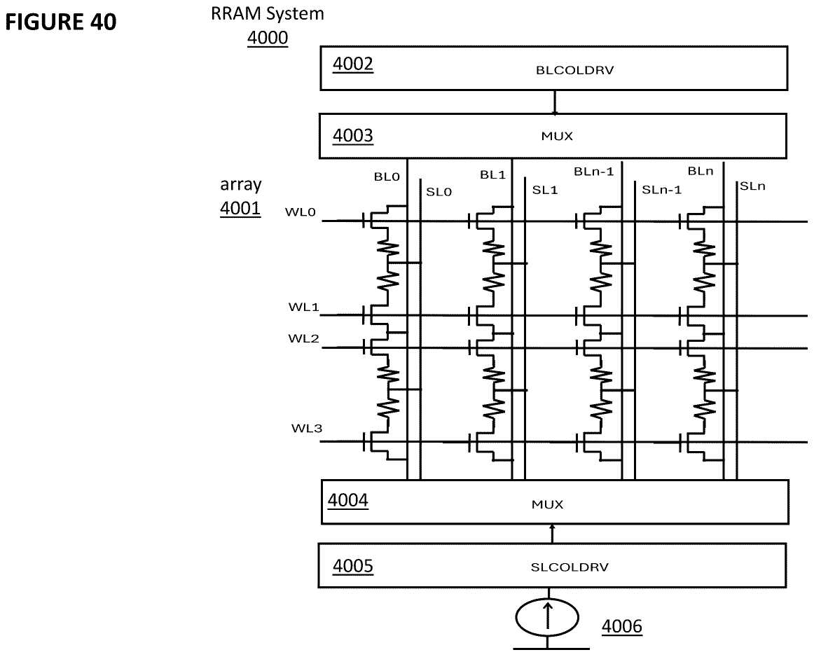

FIG. 40 depicts RRAM system 4000, which comprises RRAM array 4001, bit line column driver 4002, multiplexor 4003, multiplexor 4004, source line column driver 4005, and current limiter 4006. Current limiter 4006 limits the amount of current drawn or applied by bit line column driver 4002 and source line column driver 4005 to provide protection in the event a short circuit occurs and to control the temperature of RRAM system 4000.

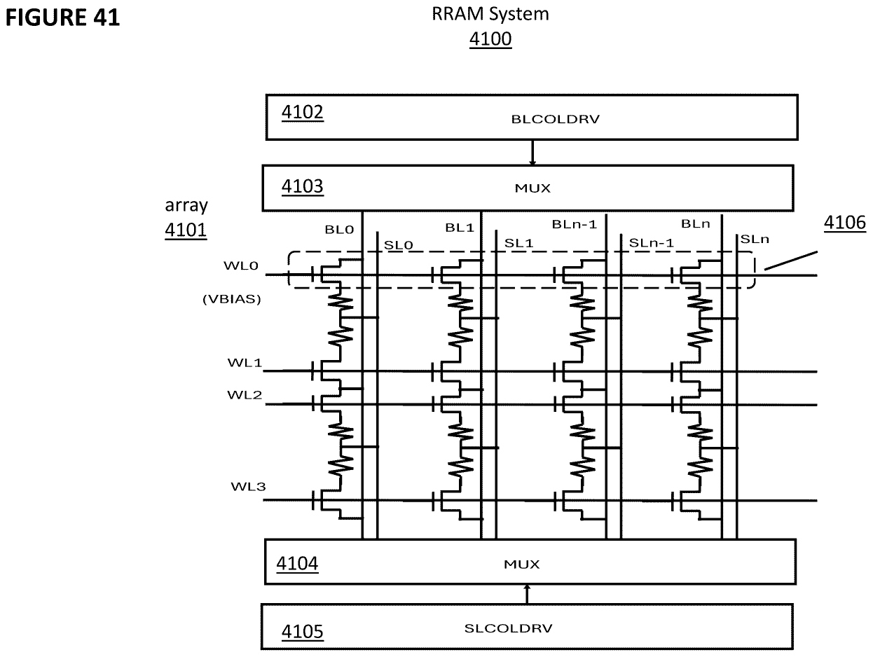

FIG. 41 depicts RRAM system 4100, which comprises RRAM array 4101, bit line column driver 4102, multiplexor 4103, multiplexor 4104, and source line column driver 4105. The select transistors 4106 in one of the rows of RRAM array 4101 (here, the top row) receives a bias signal, VBIAS, on their gates, which causes each of the select transistors 4106 to act as a current limiter for its column and to limit the amount of current drawn or applied by bit line column driver 4102 and source line column driver 4105 for that particular column to provide protection in the event a short circuit occurs and to control the temperature of RRAM system 4100.

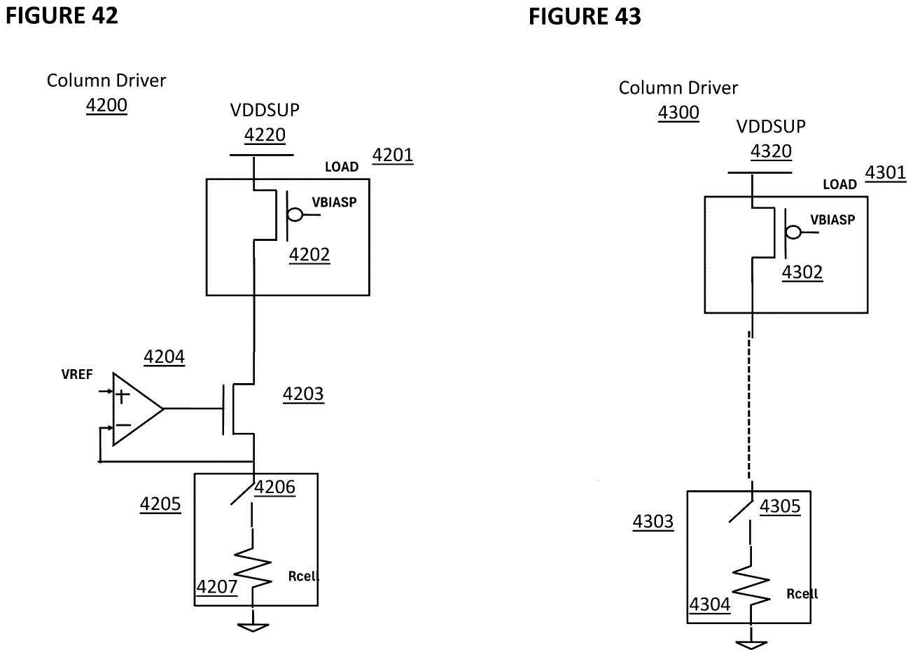

FIG. 42 depicts column driver 4200. Column driver 4200 is coupled to RRAM unit 4205, which comprises select transistor 4206 and RRAM cell 4207. Column driver 4200 comprises load 4201, NMOS transistor 4203, and operational amplifier 4204. Load 4201 in this example comprises PMOS transistor 4202 receiving bias voltage VBIASP on its gate to control its current. Voltage source 4220 provides a voltage to the source of PMOS 4202 and optionally is trimmable.

FIG. 43 depicts column driver 4300. Column driver 4300 is coupled to RRAM unit 4303, which comprises select transistor 4305 and RRAM cell 4304. Column driver 4300 comprises load 4301. Load 4301 in this example comprises PMOS transistor 4302 receiving bias voltage VBIASP on its gate to control its current. Voltage source 4320 provides a voltage to the source of PMOS 4302 and optionally is trimmable.

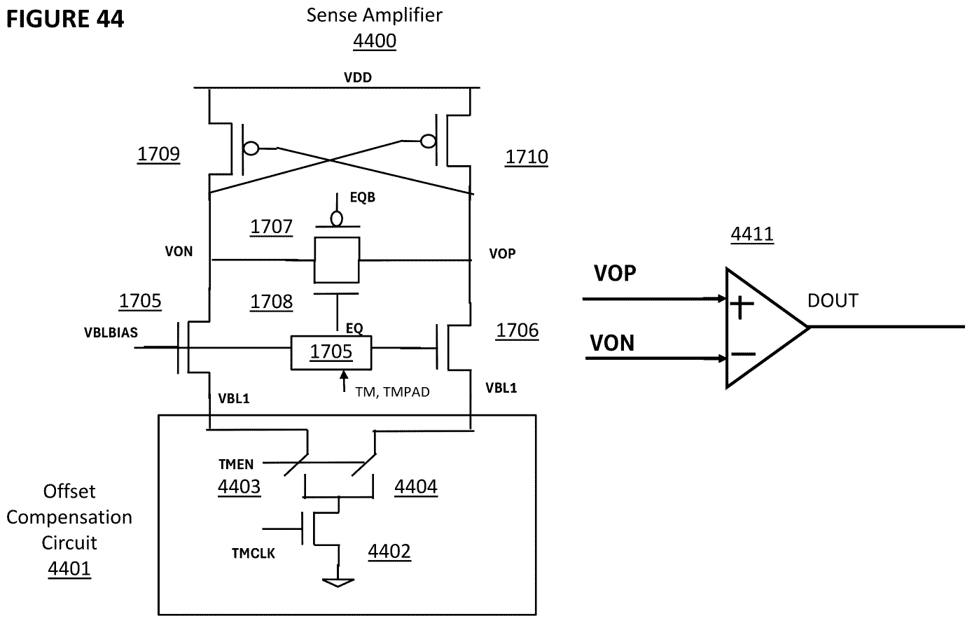

FIG. 44 shows a sense amplifier 4400 with an offset compensation circuit 4401.

Sense amplifier 4400 is similar to sense amplifier 2200 in FIG. 22 with the addition of offset compensation circuit 4401. The components contained in sense amplifier 2200 are shown here and will not be explained for efficiency's sake. During normal operation, sense amplifier 4400 will be coupled to RRAM units (not shown). During a testing mode, sense amplifier 4400 is coupled to offset test circuit 4401.

Offset compensation circuit 4401 comprises multiplexors 4403 and 4404 and a tailed NMSO transistor 4402 that is enabled by a clock signal, TMCLK. Multiplexors 4403 and 4404 are enabled by a testmode control signal to connect NMOS transistors 1705 and 1706 to NMOS transistor 4402 to cause sense amplifier 4400 to operate as a differential amplifier. This is then used to calibrate the offset of the read path such as shown in FIG. 37. Comparator 4411 compares VOP and VON.

References to the present invention herein are not intended to limit the scope of any claim or claim term, but instead merely make reference to one or more features that may be covered by one or more of the claims. Materials, processes and numerical examples described above are examples only, and should not be deemed to limit the claims. It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between). For example, forming an element “over a substrate” can include forming the element directly on the substrate with no intermediate materials/elements there between, as well as forming the element indirectly on the substrate with one or more intermediate materials/elements there between.

What is claimed is:

1. A system comprising:
an array of resistive random access memory (RRAM) units arranged in rows and columns; and
a sense amplifier for determining a differential value stored in a first RRAM unit and a second RRAM unit in the array, wherein the first RRAM unit comprises a first select transistor coupled to a first set of one or more RRAM cells and the second RRAM unit comprises a second select transistor coupled to a second set of one or more RRAM cells.

2. The system of claim 1, where the first set comprises one RRAM cell and the second set comprises one RRAM cell.

3. The system of claim 1, wherein the first set comprises two RRAM cells and the second set comprises two RRAM cells.

4. The system of claim 1, wherein the first set comprises more than two RRAM cells and the second set comprises more than two RRAM cells.

5. A system comprising:
an array of resistive random access memory (RRAM) units arranged in rows and columns; and
a sense amplifier for determining a value stored in a RRAM unit in the array using a reference unit.

6. The system of claim 5, wherein the RRAM unit comprises a RRAM cell and a select transistor.

7. The system of claim 5, wherein the RRAM unit comprises a first RRAM cell, a second RRAM cell, and a select transistor.

8. The system of claim 5, wherein the sense amplifier determines a state of a RRAM cell in a RRAM unit using the reference unit.

9. The system of claim 5, wherein the reference unit comprises a RRAM cell.
